(19) United States
(12) Patent Application Publication
(10) Pub. No.: US 2023/0028608 A1
(43) Pub. Date: Jan. 26, 2023

(54) LIDAR SYSTEM WITH PULSE-ENERGY MEASUREMENT

(71) Applicant: Luminar, LLC, Orlando, FL (US)

(72) Inventors: Lawrence Shah, Winter Park, FL (US); David H. Minasi, Lauderdale-by-the-Sea, FL (US)

(21) Appl. No.: 17/870,132

(22) Filed: Jul. 21, 2022

Related U.S. Application Data
(60) Provisional application No. 63/224,936, filed on Jul. 23, 2021.

(51) Int. Cl. G01S 17/10; G01S 7/4865; G01S 7/481; G01R 29/027; G01S 7/484

(52) U.S. Cl. CPC G01S 17/10; G01R 29/027; G01S 7/484; G01S 7/4817; G01S 7/4818; G01S 7/4865

(57) ABSTRACT

A system includes a light source, an optical splitter, and a pulse-energy measurement circuit. The light source is configured to generate an emitted beam of light that includes an emitted pulse of light. The optical splitter is configured to split the emitted beam of light to produce at least (i) a test beam of light that includes a test pulse of light, the test pulse of light including a first portion of the emitted pulse of light and (ii) an output beam of light that includes an output pulse of light, the output pulse of light including a second portion of the emitted pulse of light allowed to at least in part exit the system. The pulse-energy measurement circuit is configured to receive the test pulse of light and determine a numerical value corresponding to an individual energy amount of the test pulse of light.

### CROSS REFERENCE TO OTHER APPLICATIONS

This application claims priority to U.S. Provisional Pat. Application No. 63/224,936 entitled LIDAR SYSTEM WITH PULSE-ENERGY MEASUREMENT filed Jul. 23, 2021 which is incorporated herein by reference for all purposes.

### BACKGROUND OF THE INVENTION

Light detection and ranging (lidar) is a technology that can be used to measure distances to remote targets. Typically, a lidar system includes a light source and an optical receiver. The light source can include, for example, a laser which emits light having a particular operating wavelength. The operating wavelength of a lidar system may lie, for example, in the infrared, visible, or ultraviolet portions of the electromagnetic spectrum. The light source emits light toward a target which scatters the light, and some of the scattered light is received back at the receiver. The system determines the distance to the target based on one or more characteristics associated with the received light. For example, the lidar system may determine the distance to the target based on the time of flight for a pulse of light emitted by the light source to travel to the target and back to the lidar system.

### BRIEF DESCRIPTION OF THE DRAWINGS

Various embodiments of the invention are disclosed in the following detailed description and the accompanying drawings.

FIG. 1 illustrates an example light detection and ranging (lidar) system.

FIG. 2 illustrates an example scan pattern produced by a lidar system.

FIG. 3 illustrates an example lidar system with an example rotating polygon mirror.

FIG. 4 illustrates an example light-source field of view (FOVL) and receiver field of view (FOV_{R}) for a lidar system.

FIG. 5 illustrates an example unidirectional scan pattern that includes multiple pixels and multiple scan lines.

FIG. 6 illustrates an example light source, optical splitter, and pulse-energy measurement circuit.

FIG. 7 illustrates an example free-space optical splitter.

FIG. 8 illustrates an example fiber-optic splitter.

FIG. 9 illustrates an example light source, optical splitter, and pulse-energy measurement circuit, where the light source includes a seed laser diode and a semiconductor optical amplifier (SOA).

FIG. 10 illustrates an example light source, optical splitter, and pulse-energy measurement circuit, where the light source includes a seed laser diode, a semiconductor optical amplifier (SOA), and a fiber-optic amplifier.

FIG. 11 illustrates an example fiber-optic amplifier.

FIG. 12 illustrates an example pulse-energy measurement circuit that includes a peak-hold circuit and an analog-to-digital converter (ADC).

FIG. 13 illustrates an example pulse-energy measurement circuit that includes multiple comparators and time-to-digital converters (TDCs).

FIG. 14 illustrates an example lidar system that includes an optical splitter and pulse-energy measurement circuit.

FIG. 15 illustrates an example graph of the optical power of an output beam plotted versus time.

FIG. 16 is a flow chart illustrating an embodiment of a process of a lidar system for detecting objects.

FIG. 17 is a flow chart illustrating an embodiment of a process for monitoring a light pulse of an emitted light beam.

FIG. 18 is a flow chart illustrating an embodiment of a process for determining monitoring measurements for a light pulse.

FIG. 19 is a flow chart illustrating an embodiment of a process for initiating signal analysis on a light pulse.

FIG. 20 is a flow chart illustrating an embodiment of a process for outputting a peak hold voltage signal for measuring a light pulse.

FIG. 21 illustrates an example computer system.

### DETAILED DESCRIPTION

The invention can be implemented in numerous ways, including as a process; an apparatus; a system; a composition of matter; a computer program product embodied on a computer readable storage medium; and/or a processor, such as a processor configured to execute instructions stored on and/or provided by a memory coupled to the processor. In this specification, these implementations, or any other form that the invention may take, may be referred to as techniques. In general, the order of the steps of disclosed processes may be altered within the scope of the invention. Unless stated otherwise, a component such as a processor or a memory described as being configured to perform a task may be implemented as a general component that is temporarily configured to perform the task at a given time or a specific component that is manufactured to perform the task. As used herein, the term ‘processor’ refers to one or more devices, circuits, and/or processing cores configured to process data, such as computer program instructions.

A detailed description of one or more embodiments of the invention is provided below along with accompanying figures that illustrate the principles of the invention. The invention is described in connection with such embodiments, but the invention is not limited to any embodiment. The scope of the invention is limited only by the claims and the invention encompasses numerous alternatives, modifications and equivalents. Numerous specific details are set forth in the following description in order to provide a thorough understanding of the invention. These details are provided for the purpose of example and the invention may be practiced according to the claims without some or all of these specific details. For the purpose of clarity, technical material that is known in the technical fields related to the invention has not been described in detail so that the invention is not unnecessarily obscured.

A lidar system with pulse-energy measurement is disclosed. Using the disclosed systems and techniques, the pulse energy associated with individual output light pulses from a lidar system can be measured. For example, using pulse-energy measurement circuitry integrated into a lidar system, the pulse energy for individual pulses can be measured at various points in a lidar scan. In some embodiments, the lidar output beam is split and a portion of the output beam is sent to a pulse-energy circuit as a test pulse associated with an output pulse. The pulse-energy circuit measures the peak voltage of the test pulse and can output a numerical value corresponding to the individual energy amount of the test pulse and related output pulse. In some embodiments, the pulse-energy circuit is a pulse-energy measurement circuit that includes a detector, such as a photodetector. The detector outputs a photocurrent associated with the test pulse that is converted by the pulse-energy measurement circuit to a corresponding voltage pulse. The voltage pulse is then analyzed by the pulse-energy measurement circuit to determine a numerical value corresponding to the pulse energy of the test pulse. For example, a peak voltage can be detected and used to determine a corresponding numerical value. A processor and/or controller of the lidar system determines the energy of the test and/or output pulse based on the determined corresponding numerical value.

In various embodiments, the output signal of the pulse-energy measurement circuit can be used to monitor and/or manage the performance of the lidar system. For example, the pulse measurements can be used to provide feedback to power down or up the output beam such as reducing the laser output during an eclipse period and/or changing the laser output during a scan, such as changing the output as a function of scan angle. In some embodiments, an instruction can be sent to adjust the energy of emitted light pulses that results in a decrease in energy for subsequently emitted pulses to a level below a particular threshold energy. In various embodiments, the instruction is applied to subsequently emitted light pulses that are directed by the scanner away from the window of the lidar system such as during an eclipse period. In some embodiments, the pulse measurements can be used to improve the accuracy of lidar results, such as improving reflectance accuracy, and/or can be used to implement failover techniques such as in the case of a detected malfunction, among other uses. For example, in the event the pulse measurements are outside the expected operating range, an alert can be triggered to address the detected condition. In some embodiments, the alert is used to shut down the lidar system or place the lidar system in a secondary or failover mode. As another example, the pulse-energy measurements allow for pulse output variation as a function of the field of regard such as when transitioning from a region of interest to the periphery. The pulse-energy measurement circuit allows for confirmation that the output pulses corresponding to different regions of a field of regard are within expected values. In some embodiments, there may be a latency associated with the feedback provided by pulse-energy measurements and the system accounts for the delay when measuring/modifying the output pulses.

In some embodiments, a system comprises at least a light source, an optical splitter, and a pulse-energy measurement circuit. For example, a lidar system operates in a vehicle and includes at least a light source, an optical splitter, and a pulse-energy measurement circuit. The light source is configured to generate an emitted beam of light comprising an emitted pulse of light. For example, the light source can emit a light pulse at one or more particular wavelengths. The optical splitter is configured to split the emitted beam of light to produce at least (i) a test beam of light comprising a test pulse of light and (ii) an output beam of light comprising an output pulse of light. The test pulse of light comprises a first portion of the emitted pulse of light. The output pulse of light comprises a second portion of the emitted pulse of light allowed to at least in part exit the system. For example, the output pulse of light exits a lidar system as part of a scanning technique to scan a field of regard. In various embodiments, the pulse-energy measurement circuit is configured to receive the test pulse of light and determine a numerical value corresponding to an individual energy amount of the test pulse of light. For example, the test pulse of light is directed to a pulse-energy measurement circuit where the peak voltage of the test pulse is measured. The measured value can be used to determine a corresponding measure for the output pulse of light. In various embodiments, a pulse-energy measurement can be determined from the output of the pulse-energy measurement circuit and used to determine whether the output pulse of light and/or system is operating as intended, such as within an operating energy range. For example, in the event the test pulse of light is not found to be operating as expected, such as outside the operating energy range, an alert, such as an alert that the system is not operating properly, can be triggered for the system. As another example, a pulse-energy measurement can be used to send an instruction to adjust the energy of one or more subsequent emitted output pulses and/or to confirm that the energy of a subsequent emitted pulse was adjusted consistent with an instruction.

In some embodiments, the pulse-energy measurement circuit includes a detector, an electronic amplifier, a peak-hold circuit, and an analog-to-digital converter (ADC). The detector is configured to produce a pulse of photocurrent corresponding to the test pulse of light. The electronic amplifier is configured to produce a voltage pulse corresponding to the pulse of photocurrent and the peak-hold circuit is configured to produce a voltage signal corresponding to a peak of the voltage pulse. In various embodiments, the produced voltage signal corresponds to the peak voltage of the test pulse of light. The ADC is configured to determine a numerical value corresponding to the energy of the test pulse of light, wherein the numerical value is determined based on the voltage signal corresponding to the peak of the voltage pulse. By determining a numerical value corresponding to the energy of the test pulse of light, the energy of the output pulse of light can be determined as well. In various embodiments, the determined numerical values are used by the system to monitor and/or adjust the operation of the system.

A lidar system operates in a vehicle and includes multiple “eyes,” each of which has its own field of regard, or an angular range over which the eye scans targets using pulses of light in accordance with a scan pattern. The fields of regard can combine along a certain dimension (e.g., horizontally) to define the overall field of regard of the lidar system. The lidar system then can use data received via both eyes to generate a point cloud or otherwise process the received data.

In a two-eye configuration of the lidar system, the two eyes can be housed together and scan the respective fields of regard via a shared window or separate windows, or the eyes can be housed separately. In the latter case, an assembly referred to as a “sensor head” can include a scanner, a receiver, and an optical element such as a collimator or a laser diode to generate or convey a beam of light.

Depending on the implementation, each eye of a lidar system can include a separate scanner (e.g., each eye can be equipped with a pivotable scan mirror to scan the field of regard vertically and another pivotable scan mirror to scan the field of regard horizontally), a partially shared scanner (e.g., each eye can be equipped with a pivotable scan mirror to scan the field of regard vertically, and a shared polygon mirror can scan the corresponding fields of regard horizontally, using different reflective surfaces), or a fully shared scanner (e.g., a pivotable planar mirror can scan the fields of regard vertically by reflecting incident beams at different regions on the reflective surface, and a shared polygon mirror can scan the corresponding fields of regard horizontally, using different reflective surfaces).

Different hardware configurations allow the lidar system to operate the eyes more independently of each other, as is the case with separate scanners, or less independently, as is the case with a fully shared scanner. For example, the two or more eyes may scan the respective fields of regard using similar or different scan patterns. In one implementation, the two eyes trace out the same pattern, but with a certain time differential to maintain angular separation between light-source fields of view and thereby reduce the probability of cross-talk events between the sensor heads. In another implementation, the two eyes scan the corresponding fields of regard according to different scan patterns, at least in some operational states (e.g., when the vehicle is turning right or left).

Further, according to one approach, two eyes of a lidar system are arranged so that the fields of regard of the eyes are adjacent and non-overlapping. For example, each field of regard can span approximately 60 degrees horizontally and 30 degrees vertically, so that the combined field of regard of the lidar system spans approximately 120 degrees horizontally and 30 degrees vertically. The corresponding scanners (or paths within a shared scanner) can point away from each other at a certain angle, for example, so that the respective fields of regard abut approximately at an axis corresponding to the forward-facing direction of the vehicle.

Alternatively, the lidar system can operate in a “cross-eyed” configuration to create an area of overlap between the fields of regard. The area of overlap can be approximately centered along the forward-facing direction or another direction, which in some implementations a controller can determine dynamically. In this implementation, the two sensor heads can yield a higher density of scan in the area that generally is more important. In some implementations, the fields of regard in a cross-eyed two-eye configuration are offset from each other by a half-pixel value, so that the area of overlap has twice as many pixels. In general, the fields of regard can overlap angularly or translationally. To reduce the probability of cross-talk events (e.g., the situation when a pulse emitted by the light source associated with the first eye is received by the receiver of the second eye), the lidar system can use output beams with different wavelengths.

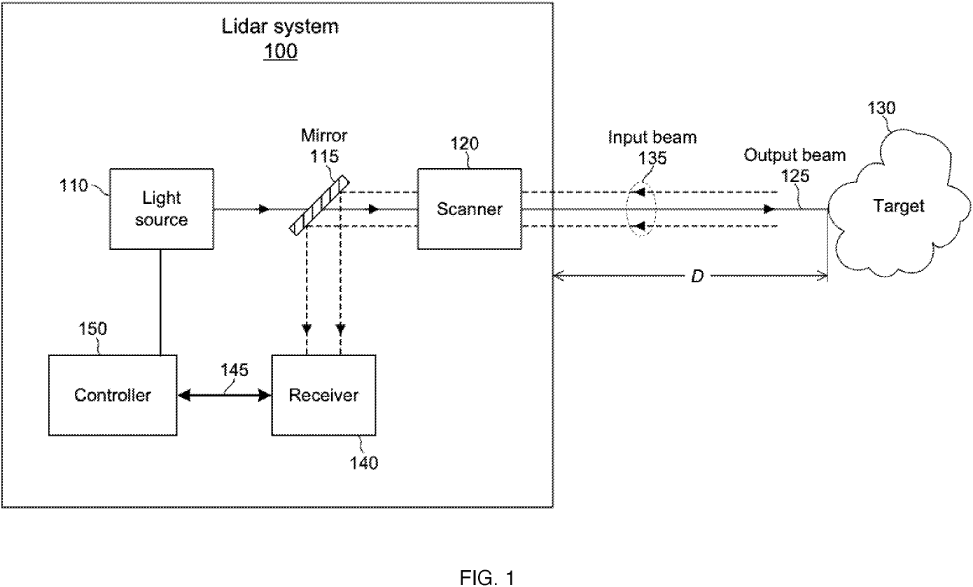

FIG. 1 illustrates an example light detection and ranging (lidar) system 100. In particular embodiments, a lidar system 100 may be referred to as a laser ranging system, a laser radar system, a LIDAR system, a lidar sensor, or a laser detection and ranging (LADAR or ladar) system. In particular embodiments, a lidar system 100 may include a light source 110, mirror 115, scanner 120, receiver 140, or controller 150. The light source 110 may include, for example, a laser which emits light having a particular operating wavelength in the infrared, visible, or ultraviolet portions of the electromagnetic spectrum. As an example, light source 110 may include a laser with one or more operating wavelengths between approximately 900 nanometers (nm) and 2000 nm. The light source 110 emits an output beam of light 125 which may be continuous wave (CW), pulsed, or modulated in any suitable manner for a given application. The output beam of light 125 is directed downrange toward a remote target 130. As an example, the remote target 130 may be located a distance D of approximately 1 m to 1 km from the lidar system 100. Although not shown in FIG. 1, when outputting light pulses as part of output beam 125, lidar system 100 can include pulse-energy measurement circuitry as disclosed herein used to determine the pulse energy associated with individual output light pulses.

Once the output beam 125 reaches the downrange target 130, the target may scatter or reflect at least a portion of light from the output beam 125, and some of the scattered or reflected light may return toward the lidar system 100. In the example of FIG. 1, the scattered or reflected light is represented by input beam 135, which passes through scanner 120 and is reflected by mirror 115 and directed to receiver 140. In particular embodiments, a relatively small fraction of the light from output beam 125 may return to the lidar system 100 as input beam 135. As an example, the ratio of input beam 135 average power, peak power, or pulse energy to output beam 125 average power, peak power, or pulse energy may be approximately 10⁻¹, 10⁻², 10⁻³, 10⁻⁴, 10⁻⁵, 10⁻⁶, 10⁻⁷, 10⁻⁸, 10⁻⁹, 10⁻¹⁰, 10^{-11,} or 10⁻¹². As another example, if a pulse of output beam 125 has a pulse energy of 1 microjoule (µJ), then the pulse energy of a corresponding pulse of input beam 135 may have a pulse energy of approximately 10 nanojoules (nJ), 1 nJ, 100 picojoules (pJ), 10 pJ, 1 pJ, 100 femtojoules (fJ), 10 fJ, 1 fJ, 100 attojoules (aJ), 10 aJ, 1 aJ, or 0.1 aJ. In some embodiments, the pulse energy of a pulse of input beam 135 can at times be as large as the pulse energy of a corresponding pulse of output beam 125.

In particular embodiments, output beam 125 may include or may be referred to as an optical signal, output optical signal, emitted optical signal, output light, emitted pulse of light, laser beam, light beam, optical beam, emitted beam, emitted light, or beam. In particular embodiments, input beam 135 may include or may be referred to as a received optical signal, received pulse of light, input pulse of light, input optical signal, return beam, received beam, return light, received light, input light, scattered light, or reflected light. As used herein, scattered light may refer to light that is scattered or reflected by a target 130. As an example, an input beam 135 may include: light from the output beam 125 that is scattered by target 130; light from the output beam 125 that is reflected by target 130; or a combination of scattered and reflected light from target 130.

In particular embodiments, receiver 140 may receive or detect photons from input beam 135 and produce one or more representative signals. For example, the receiver 140 may produce an output electrical signal 145 that is representative of the input beam 135, and the electrical signal 145 may be sent to controller 150. In particular embodiments, receiver 140 or controller 150 may include a processor, computing system (e.g., an ASIC or FPGA), or other suitable circuitry. A controller 150 may be configured to analyze one or more characteristics of the electrical signal 145 from the receiver 140 to determine one or more characteristics of the target 130, such as its distance downrange from the lidar system 100. This may be done, for example, by analyzing a time of flight or a frequency or phase of a transmitted beam of light 125 or a received beam of light 135. If lidar system 100 measures a time of flight of T (e.g., T represents a round-trip time of flight for an emitted pulse of light to travel from the lidar system 100 to the target 130 and back to the lidar system 100), then the distance D from the target 130 to the lidar system 100 may be expressed as D = c. T/2, where c is the speed of light (approximately 3.0X10⁸ m/s). As an example, if a time of flight is measured to be T= 300 ns, then the distance from the target 130 to the lidar system 100 may be determined to be approximately D = 45.0 m. As another example, if a time of flight is measured to be T = 1.33 µs, then the distance from the target 130 to the lidar system 100 may be determined to be approximately D = 199.5 m. In particular embodiments, a distance D from lidar system 100 to a target 130 may be referred to as a distance, depth, or range of target 130. As used herein, the speed of light c refers to the speed of light in any suitable medium, such as for example in air, water, or vacuum. As an example, the speed of light in vacuum is approximately 2.9979×10⁸ m/s, and the speed of light in air (which has a refractive index of approximately 1.0003) is approximately 2.9970×10⁸ m/s.

In particular embodiments, light source 110 may include a pulsed or CW laser. As an example, light source 110 may be a pulsed laser configured to produce or emit pulses of light with a pulse duration or pulse width of approximately 10 picoseconds (ps) to 100 nanoseconds (ns). The pulses may have a pulse duration of approximately 100 ps, 200 ps, 400 ps, 1 ns, 2 ns, 5 ns, 10 ns, 20 ns, 50 ns, 100 ns, or any other suitable pulse duration. As another example, light source 110 may be a pulsed laser that produces pulses with a pulse duration of approximately 1-5 ns. As another example, light source 110 may be a pulsed laser that produces pulses at a pulse repetition frequency of approximately 100 kHz to 10 MHz or a pulse period (e.g., a time between consecutive pulses) of approximately 100 ns to 10 µs. In particular embodiments, light source 110 may have a substantially constant pulse repetition frequency, or light source 110 may have a variable or adjustable pulse repetition frequency. As an example, light source 110 may be a pulsed laser that produces pulses at a substantially constant pulse repetition frequency of approximately 640 kHz (e.g., 640,000 pulses per second), corresponding to a pulse period of approximately 1.56 µs. As another example, light source 110 may have a pulse repetition frequency (which may be referred to as a repetition rate) that can be varied from approximately 200 kHz to 3 MHz. As used herein, a pulse of light may be referred to as an optical pulse, a light pulse, or a pulse.

In some embodiments, light source 110 may emit pulses at different wavelengths and with a particular encoding time delay between the pulses of different wavelengths. For example, two different groups of pulses can each include pulses of different wavelengths and each pulse group can utilize a different encoding time delay.

In particular embodiments, light source 110 may include a pulsed or CW laser that produces a free-space output beam 125 having any suitable average optical power. As an example, output beam 125 may have an average power of approximately 1 milliwatt (mW), 10 mW, 100 mW, 1 watt (W), 10 W, or any other suitable average power. In particular embodiments, output beam 125 may include optical pulses with any suitable pulse energy or peak optical power. As an example, output beam 125 may include pulses with a pulse energy of approximately 0.01 µJ, 0.1 µJ, 0.5 µJ, 1 µJ, 2 µJ, 10 µJ, 100 µJ, 1 mJ, or any other suitable pulse energy. As another example, output beam 125 may include pulses with a peak power of approximately 10 W, 100 W, 1 kW, 5 kW, 10 kW, or any other suitable peak power. The peak power (Pₚₑₐₖ) of a pulse of light can be related to the pulse energy (E) by the expression E=Pₚₑₐₖ·Δt, where Δt is the duration of the pulse, and the duration of a pulse may be defined as the full width at half maximum duration of the pulse. For example, an optical pulse with a duration of 1 ns and a pulse energy of 1 µJ has a peak power of approximately 1 kW. The average power (Pₐᵥ) of an output beam 125 can be related to the pulse repetition frequency (PRF) and pulse energy by the expression Pₐᵥ = PRF·E. For example, if the pulse repetition frequency is 500 kHz, then the average power of an output beam 125 with 1-µJ pulses is approximately 0.5 W.

In particular embodiments, light source 110 may include a laser diode, such as for example, a Fabry-Perot laser diode, a quantum well laser, a distributed Bragg reflector (DBR) laser, a distributed feedback (DFB) laser, a vertical-cavity surface-emitting laser (VCSEL), a quantum dot laser diode, a grating-coupled surface-emitting laser (GCSEL), a slab-coupled optical waveguide laser (SCOWL), a single-transverse-mode laser diode, a multi-mode broad area laser diode, a laser-diode bar, a laser-diode stack, or a tapered-stripe laser diode. As an example, light source 110 may include an aluminum-gallium-arsenide (AlGaAs) laser diode, an indium-gallium-arsenide (InGaAs) laser diode, an indium-gallium-arsenide-phosphide (InGaAsP) laser diode, or a laser diode that includes any suitable combination of aluminum (Al), indium (In), gallium (Ga), arsenic (As), phosphorous (P), or any other suitable material. In particular embodiments, light source 110 may include a pulsed or CW laser diode with a peak emission wavelength between 1200 nm and 1600 nm. As an example, light source 110 may include a current-modulated InGaAsP DFB laser diode that produces optical pulses at a wavelength of approximately 1550 nm. As another example, light source 110 may include a laser diode that emits light at a wavelength between 1500 nm and 1510 nm.

In particular embodiments, light source 110 may include a pulsed or CW laser diode followed by one or more optical-amplification stages. For example, a seed laser diode may produce a seed optical signal, and an optical amplifier may amplify the seed optical signal to produce an amplified optical signal that is emitted by the light source 110. In particular embodiments, an optical amplifier may include a fiber-optic amplifier or a semiconductor optical amplifier (SOA). For example, a pulsed laser diode may produce relatively low-power optical seed pulses which are amplified by a fiber-optic amplifier. As another example, a light source 110 may include a fiber-laser module that includes a current-modulated laser diode with an operating wavelength of approximately 1550 nm followed by a single-stage or a multi-stage erbium-doped fiber amplifier (EDFA) or erbium-ytterbium-doped fiber amplifier (EYDFA) that amplifies the seed pulses from the laser diode. As another example, light source 110 may include a continuous-wave (CW) or quasi-CW laser diode followed by an external optical modulator (e.g., an electro-optic amplitude modulator). The optical modulator may modulate the CW light from the laser diode to produce optical pulses which are sent to a fiber-optic amplifier or SOA. As another example, light source 110 may include a pulsed or CW seed laser diode followed by a semiconductor optical amplifier (SOA). The SOA may include an active optical waveguide configured to receive light from the seed laser diode and amplify the light as it propagates through the waveguide. The optical gain of the SOA may be provided by pulsed or direct-current (DC) electrical current supplied to the SOA. The SOA may be integrated on the same chip as the seed laser diode, or the SOA may be a separate device with an anti-reflection coating on its input facet or output facet. As another example, light source 110 may include a seed laser diode followed by an SOA, which in turn is followed by a fiber-optic amplifier. For example, the seed laser diode may produce relatively low-power seed pulses which are amplified by the SOA, and the fiber-optic amplifier may further amplify the optical pulses.

In particular embodiments, light source 110 may include a direct-emitter laser diode. A direct-emitter laser diode (which may be referred to as a direct emitter) may include a laser diode which produces light that is not subsequently amplified by an optical amplifier. A light source 110 that includes a direct-emitter laser diode may not include an optical amplifier, and the output light produced by a direct emitter may not be amplified after it is emitted by the laser diode. The light produced by a direct-emitter laser diode (e.g., optical pulses, CW light, or frequency-modulated light) may be emitted directly as a free-space output beam 125 without being amplified. A direct-emitter laser diode may be driven by an electrical power source that supplies current pulses to the laser diode, and each current pulse may result in the emission of an output optical pulse.

In particular embodiments, light source 110 may include a diode-pumped solid-state (DPSS) laser. A DPSS laser (which may be referred to as a solid-state laser) may refer to a laser that includes a solid-state, glass, ceramic, or crystal-based gain medium that is pumped by one or more pump laser diodes. The gain medium may include a host material that is doped with rare-earth ions (e.g., neodymium, erbium, ytterbium, or praseodymium). For example, a gain medium may include a yttrium aluminum garnet (YAG) crystal that is doped with neodymium (Nd) ions, and the gain medium may be referred to as a Nd:YAG crystal. A DPSS laser with a Nd:YAG gain medium may produce light at a wavelength between approximately 1300 nm and approximately 1400 nm, and the Nd:YAG gain medium may be pumped by one or more pump laser diodes with an operating wavelength between approximately 730 nm and approximately 900 nm. A DPSS laser may be a passively Q-switched laser that includes a saturable absorber (e.g., a vanadium-doped crystal that acts as a saturable absorber). Alternatively, a DPSS laser may be an actively Q-switched laser that includes an active Q-switch (e.g., an acousto-optic modulator or an electro-optic modulator). A passively or actively Q-switched DPSS laser may produce output optical pulses that form an output beam 125 of a lidar system 100.

In particular embodiments, an output beam of light 125 emitted by light source 110 may be a collimated optical beam having any suitable beam divergence, such as for example, a full-angle beam divergence of approximately 0.5 to 10 milliradians (mrad). A divergence of output beam 125 may refer to an angular measure of an increase in beam size (e.g., a beam radius or beam diameter) as output beam 125 travels away from light source 110 or lidar system 100. In particular embodiments, output beam 125 may have a substantially circular cross section with a beam divergence characterized by a single divergence value. As an example, an output beam 125 with a circular cross section and a full-angle beam divergence of 2 mrad may have a beam diameter or spot size of approximately 20 cm at a distance of 100 m from lidar system 100. In particular embodiments, output beam 125 may have a substantially elliptical cross section characterized by two divergence values. As an example, output beam 125 may have a fast axis and a slow axis, where the fast-axis divergence is greater than the slow-axis divergence. As another example, output beam 125 may be an elliptical beam with a fast-axis divergence of 4 mrad and a slow-axis divergence of 2 mrad.

In particular embodiments, an output beam of light 125 emitted by light source 110 may be unpolarized or randomly polarized, may have no specific or fixed polarization (e.g., the polarization may vary with time), or may have a particular polarization (e.g., output beam 125 may be linearly polarized, elliptically polarized, or circularly polarized). As an example, light source 110 may produce light with no specific polarization or may produce light that is linearly polarized.

In particular embodiments, lidar system 100 may include one or more optical components configured to reflect, focus, filter, shape, modify, steer, or direct light within the lidar system 100 or light produced or received by the lidar system 100 (e.g., output beam 125 or input beam 135). As an example, lidar system 100 may include one or more lenses, mirrors, filters (e.g., band-pass or interference filters), beam splitters, optical splitters, polarizers, polarizing beam splitters, wave plates (e.g., half-wave or quarter-wave plates), diffractive elements, holographic elements, isolators, couplers, detectors, beam combiners, or collimators. The optical components in a lidar system 100 may be free-space optical components, fiber-coupled optical components, or a combination of free-space and fiber-coupled optical components.

In particular embodiments, lidar system 100 may include a telescope, one or more lenses, or one or more mirrors configured to expand, focus, or collimate the output beam 125 or the input beam 135 to a desired beam diameter or divergence. As an example, the lidar system 100 may include one or more lenses to focus the input beam 135 onto a photodetector of receiver 140. As another example, the lidar system 100 may include one or more flat mirrors or curved mirrors (e.g., concave, convex, or parabolic mirrors) to steer or focus the output beam 125 or the input beam 135. For example, the lidar system 100 may include an off-axis parabolic mirror to focus the input beam 135 onto a photodetector of receiver 140. As illustrated in FIG. 1, the lidar system 100 may include mirror 115 (which may be a metallic or dielectric mirror), and mirror 115 may be configured so that light beam 125 passes through the mirror 115 or passes along an edge or side of the mirror 115 and input beam 135 is reflected toward the receiver 140. As an example, mirror 115 (which may be referred to as an overlap mirror, superposition mirror, or beam-combiner mirror) may include a hole, slot, or aperture which output light beam 125 passes through. As another example, rather than passing through the mirror 115, the output beam 125 may be directed to pass alongside the mirror 115 with a gap (e.g., a gap of width approximately 0.1 mm, 0.5 mm, 1 mm, 2 mm, 5 mm, or 10 mm) between the output beam 125 and an edge of the mirror 115.

In particular embodiments, mirror 115 may provide for output beam 125 and input beam 135 to be substantially coaxial so that the two beams travel along approximately the same optical path (albeit in opposite directions). The input and output beams being substantially coaxial may refer to the beams being at least partially overlapped or sharing a common propagation axis so that input beam 135 and output beam 125 travel along substantially the same optical path (albeit in opposite directions). As an example, output beam 125 and input beam 135 may be parallel to each other to within less than 10 mrad, 5 mrad, 2 mrad, 1 mrad, 0.5 mrad, or 0.1 mrad. As output beam 125 is scanned across a field of regard, the input beam 135 may follow along with the output beam 125 so that the coaxial relationship between the two beams is maintained.

In particular embodiments, lidar system 100 may include a scanner 120 configured to scan an output beam 125 across a field of regard of the lidar system 100. As an example, scanner 120 may include one or more scanning mirrors configured to pivot, rotate, oscillate, or move in an angular manner about one or more rotation axes. The output beam 125 may be reflected by a scanning mirror, and as the scanning mirror pivots or rotates, the reflected output beam 125 may be scanned in a corresponding angular manner. As an example, a scanning mirror may be configured to periodically pivot back and forth over a 30-degree range, which results in the output beam 125 scanning back and forth across a 60-degree range (e.g., a Θ-degree rotation by a scanning mirror results in a 20-degree angular scan of output beam 125).

In particular embodiments, a scanning mirror (which may be referred to as a scan mirror) may be attached to or mechanically driven by a scanner actuator or mechanism which pivots or rotates the mirror over a particular angular range (e.g., over a 5° angular range, 30° angular range, 60° angular range, 120° angular range, 360° angular range, or any other suitable angular range). A scanner actuator or mechanism configured to pivot or rotate a mirror may include a galvanometer scanner, a resonant scanner, a piezoelectric actuator, a voice coil motor, an electric motor (e.g., a DC motor, a brushless DC motor, a synchronous electric motor, or a stepper motor), a microelectromechanical systems (MEMS) device, or any other suitable actuator or mechanism. As an example, a scanner 120 may include a scanning mirror attached to a galvanometer scanner configured to pivot back and forth over a 1° to 30° angular range. As another example, a scanner 120 may include a scanning mirror that is attached to or is part of a MEMS device configured to scan over a 1° to 30° angular range. As another example, a scanner 120 may include a polygon mirror configured to rotate continuously in the same direction (e.g., rather than pivoting back and forth, the polygon mirror continuously rotates 360 degrees in a clockwise or counterclockwise direction). The polygon mirror may be coupled or attached to a synchronous motor configured to rotate the polygon mirror at a substantially fixed rotational frequency (e.g., a rotational frequency of approximately 1 Hz, 10 Hz, 50 Hz, 100 Hz, 500 Hz, or 1,000 Hz).

In particular embodiments, scanner 120 may be configured to scan the output beam 125 (which may include at least a portion of the light emitted by light source 110) across a field of regard of the lidar system 100. A field of regard (FOR) of a lidar system 100 may refer to an area, region, or angular range over which the lidar system 100 may be configured to scan or capture distance information. As an example, a lidar system 100 with an output beam 125 with a 30-degree scanning range may be referred to as having a 30-degree angular field of regard. As another example, a lidar system 100 with a scanning mirror that rotates over a 30-degree range may produce an output beam 125 that scans across a 60-degree range (e.g., a 60-degree FOR). In particular embodiments, lidar system 100 may have a FOR of approximately 10°, 20°, 40°, 60°, 120°, 360°, or any other suitable FOR.

In particular embodiments, scanner 120 may be configured to scan the output beam 125 horizontally and vertically, and lidar system 100 may have a particular FOR along the horizontal direction and another particular FOR along the vertical direction. As an example, lidar system 100 may have a horizontal FOR of 10° to 120° and a vertical FOR of 2° to 45°. In particular embodiments, scanner 120 may include a first scan mirror and a second scan mirror, where the first scan mirror directs the output beam 125 toward the second scan mirror, and the second scan mirror directs the output beam 125 downrange from the lidar system 100. As an example, the first scan mirror may scan the output beam 125 along a first direction, and the second scan mirror may scan the output beam 125 along a second direction that is substantially orthogonal to the first direction. As another example, the first scan mirror may scan the output beam 125 along a substantially horizontal direction, and the second scan mirror may scan the output beam 125 along a substantially vertical direction (or vice versa). As another example, the first and second scan mirrors may each be driven by galvanometer scanners. As another example, the first or second scan mirror may include a polygon mirror driven by an electric motor. In particular embodiments, scanner 120 may be referred to as a beam scanner, optical scanner, or laser scanner.

In particular embodiments, one or more scanning mirrors may be communicatively coupled to controller 150 which may control the scanning mirror(s) so as to guide the output beam 125 in a desired direction downrange or along a desired scan pattern. In particular embodiments, a scan pattern may refer to a pattern or path along which the output beam 125 is directed. As an example, scanner 120 may include two scanning mirrors configured to scan the output beam 125 across a 60° horizontal FOR and a 20° vertical FOR. The two scanner mirrors may be controlled to follow a scan path that substantially covers the 60°×20° FOR. As an example, the scan path may result in a point cloud with pixels that substantially cover the 60°×20° FOR. The pixels may be approximately evenly distributed across the 60°×20° FOR. Alternatively, the pixels may have a particular nonuniform distribution (e.g., the pixels may be distributed across all or a portion of the 60°×20° FOR, and the pixels may have a higher density in one or more particular regions of the 60°×20° FOR).

In particular embodiments, a lidar system 100 may include a scanner 120 with a solid-state scanning device. A solid-state scanning device may refer to a scanner 120 that scans an output beam 125 without the use of moving parts (e.g., without the use of a mechanical scanner, such as a mirror that rotates or pivots). For example, a solid-state scanner 120 may include one or more of the following: an optical phased array scanning device; a liquid-crystal scanning device; or a liquid lens scanning device. A solid-state scanner 120 may be an electrically addressable device that scans an output beam 125 along one axis (e.g., horizontally) or along two axes (e.g., horizontally and vertically). In particular embodiments, a scanner 120 may include a solid-state scanner and a mechanical scanner. For example, a scanner 120 may include an optical phased array scanner configured to scan an output beam 125 in one direction and a galvanometer scanner that scans the output beam 125 in an orthogonal direction. The optical phased array scanner may scan the output beam relatively rapidly in a horizontal direction across the field of regard (e.g., at a scan rate of 50 to 1,000 scan lines per second), and the galvanometer may pivot a mirror at a rate of 1-30 Hz to scan the output beam 125 vertically.

In particular embodiments, a lidar system 100 may include a light source 110 configured to emit pulses of light and a scanner 120 configured to scan at least a portion of the emitted pulses of light across a field of regard of the lidar system 100. One or more of the emitted pulses of light may be scattered by a target 130 located downrange from the lidar system 100, and a receiver 140 may detect at least a portion of the pulses of light scattered by the target 130. A receiver 140 may be referred to as a photoreceiver, optical receiver, optical sensor, detector, photodetector, or optical detector. In particular embodiments, lidar system 100 may include a receiver 140 that receives or detects at least a portion of input beam 135 and produces an electrical signal that corresponds to input beam 135. As an example, if input beam 135 includes an optical pulse, then receiver 140 may produce an electrical current or voltage pulse that corresponds to the optical pulse detected by receiver 140. As another example, receiver 140 may include one or more avalanche photodiodes (APDs) or one or more single-photon avalanche diodes (SPADs). As another example, receiver 140 may include one or more PN photodiodes (e.g., a photodiode structure formed by a p-type semiconductor and an n-type semiconductor, where the PN acronym refers to the structure having p-doped and n-doped regions) or one or more PIN photodiodes (e.g., a photodiode structure formed by an undoped intrinsic semiconductor region located between p-type and n-type regions, where the PIN acronym refers to the structure having p-doped, intrinsic, and n-doped regions). An APD, SPAD, PN photodiode, or PIN photodiode may each be referred to as a detector, photodetector, or photodiode. A detector may have an active region or an avalanche-multiplication region that includes silicon, germanium, InGaAs, InAsSb (indium arsenide antimonide), AlAsSb (aluminum arsenide antimonide), or AlInAsSb (aluminum indium arsenide antimonide). The active region may refer to an area over which a detector may receive or detect input light. An active region may have any suitable size or diameter, such as for example, a diameter of approximately 10 µm, 25 µm, 50 µm, 80 µm, 100 µm, 200 µm, 500 µm, 1 mm, 2 mm, or 5 mm.

In particular embodiments, receiver 140 may include electronic circuitry that performs signal amplification, sampling, filtering, signal conditioning, analog-to-digital conversion, time-to-digital conversion, pulse detection, threshold detection, rising-edge detection, or falling-edge detection. As an example, receiver 140 may include a transimpedance amplifier that converts a received photocurrent (e.g., a current produced by an APD in response to a received optical signal) into a voltage signal. The voltage signal may be sent to pulse-detection circuitry that produces an analog or digital output signal 145 that corresponds to one or more optical characteristics (e.g., rising edge, falling edge, amplitude, duration, or energy) of a received optical pulse. As an example, the pulse-detection circuitry may perform a time-to-digital conversion to produce a digital output signal 145. The electrical output signal 145 may be sent to controller 150 for processing or analysis (e.g., to determine a time-of-flight value corresponding to a received optical pulse).

In particular embodiments, a controller 150 (which may include or may be referred to as a processor, an FPGA, an ASIC, a computer, or a computing system) may be located within a lidar system 100 or outside of a lidar system 100. Alternatively, one or more parts of a controller 150 may be located within a lidar system 100, and one or more other parts of a controller 150 may be located outside a lidar system 100. In particular embodiments, one or more parts of a controller 150 may be located within a receiver 140 of a lidar system 100, and one or more other parts of a controller 150 may be located in other parts of the lidar system 100. For example, a receiver 140 may include an FPGA or ASIC configured to process an output electrical signal from the receiver 140, and the processed signal may be sent to a computing system located elsewhere within the lidar system 100 or outside the lidar system 100. In particular embodiments, a controller 150 may include any suitable arrangement or combination of logic circuitry, analog circuitry, or digital circuitry.

In particular embodiments, controller 150 may be electrically coupled or communicatively coupled to light source 110, scanner 120, or receiver 140. As an example, controller 150 may receive electrical trigger pulses or edges from light source 110, where each pulse or edge corresponds to the emission of an optical pulse by light source 110. As another example, controller 150 may provide instructions, a control signal, a trigger signal, and/or other appropriate control signals to light source 110 indicating when light source 110 should produce optical pulses and/or the light source configuration associated with the produced optical pulses such as the desired wavelength of a light pulse. As another example, controller 150 can provide control signals to attenuate, including disabling and/or enabling, the light being generated by and emitted from light source 110. For example, controller 150 can be utilized to disable the light beam from being emitted from lidar system 100 when the beam is not aimed at target 130. Controller 150 may send an electrical trigger signal that includes electrical pulses, where each electrical pulse results in the emission of an optical pulse by light source 110. In particular embodiments, the frequency, period, duration, pulse energy, peak power, average power, or wavelength of the optical pulses produced by light source 110 may be adjusted based on instructions, a control signal, or trigger pulses provided by controller 150. In particular embodiments, controller 150 may be coupled to light source 110 and receiver 140, and controller 150 may determine a time-of-flight value for an optical pulse based on timing information associated with when the pulse was emitted by light source 110 and when a portion of the pulse (e.g., input beam 135) was detected or received by receiver 140. In particular embodiments, controller 150 may include circuitry that performs signal amplification, sampling, filtering, signal conditioning, analog-to-digital conversion, time-to-digital conversion, pulse detection, threshold detection, rising-edge detection, or falling-edge detection.

In particular embodiments, lidar system 100 may include one or more processors (e.g., a controller 150) configured to determine a distance D from the lidar system 100 to a target 130 based at least in part on a round-trip time of flight for an emitted pulse of light to travel from the lidar system 100 to the target 130 and back to the lidar system 100. The target 130 may be at least partially contained within a field of regard of the lidar system 100 and located a distance D from the lidar system 100 that is less than or equal to an operating range (R_{OP}) of the lidar system 100. In particular embodiments, an operating range (which may be referred to as an operating distance) of a lidar system 100 may refer to a distance over which the lidar system 100 is configured to sense or identify targets 130 located within a field of regard of the lidar system 100. The operating range of lidar system 100 may be any suitable distance, such as for example, 25 m, 50 m, 100 m, 200 m, 250 m, 500 m, or 1 km. As an example, a lidar system 100 with a 200-m operating range may be configured to sense or identify various targets 130 located up to 200 m away from the lidar system 100. The operating range R_{OP} of a lidar system 100 may be related to the time τ between the emission of successive optical signals by the expression R_{OP}=c·τ/2. For a lidar system 100 with a 200-m operating range (R_{OP}=200 m), the time τ between successive pulses (which may be referred to as a pulse period, a pulse repetition interval (PRI), or a time period between pulses) is approximately 2·R_{OP}/c≅1.33 µs. The pulse period τ may also correspond to the time of flight for a pulse to travel to and from a target 130 located a distance R_{OP} from the lidar system 100. Additionally, the pulse period τ may be related to the pulse repetition frequency (PRF) by the expression τ = ⅟PRF. For example, a pulse period of 1.33 µs corresponds to a PRF of approximately 752 kHz.

In particular embodiments, a lidar system 100 may be used to determine the distance to one or more downrange targets 130. By scanning the lidar system 100 across a field of regard, the system may be used to map the distance to a number of points within the field of regard. Each of these depth-mapped points may be referred to as a pixel or a voxel. A collection of pixels captured in succession (which may be referred to as a depth map, a point cloud, or a frame) may be rendered as an image or may be analyzed to identify or detect objects or to determine a shape or distance of objects within the FOR. As an example, a point cloud may cover a field of regard that extends 60° horizontally and 15° vertically, and the point cloud may include a frame of 100-2000 pixels in the horizontal direction by 4-400 pixels in the vertical direction.

In particular embodiments, lidar system 100 may be configured to repeatedly capture or generate point clouds of a field of regard at any suitable frame rate between approximately 0.1 frames per second (FPS) and approximately 1,000 FPS. As an example, lidar system 100 may generate point clouds at a frame rate of approximately 0.1 FPS, 0.5 FPS, 1 FPS, 2 FPS, 5 FPS, 10 FPS, 20 FPS, 100 FPS, 500 FPS, or 1,000 FPS. As another example, lidar system 100 may be configured to produce optical pulses at a rate of 5×10⁵ pulses/second (e.g., the system may determine 500,000 pixel distances per second) and scan a frame of 1000×50 pixels (e.g., 50,000 pixels/frame), which corresponds to a point-cloud frame rate of 10 frames per second (e.g., 10 point clouds per second). In particular embodiments, a point-cloud frame rate may be substantially fixed, or a point-cloud frame rate may be dynamically adjustable. As an example, a lidar system 100 may capture one or more point clouds at a particular frame rate (e.g., 1 Hz) and then switch to capture one or more point clouds at a different frame rate (e.g., 10 Hz). A slower frame rate (e.g., 1 Hz) may be used to capture one or more high-resolution point clouds, and a faster frame rate (e.g., 10 Hz) may be used to rapidly capture multiple lower-resolution point clouds.

In particular embodiments, a lidar system 100 may be configured to sense, identify, or determine distances to one or more targets 130 within a field of regard. As an example, a lidar system 100 may determine a distance to a target 130, where all or part of the target 130 is contained within a field of regard of the lidar system 100. All or part of a target 130 being contained within a FOR of the lidar system 100 may refer to the FOR overlapping, encompassing, or enclosing at least a portion of the target 130. In particular embodiments, target 130 may include all or part of an object that is moving or stationary relative to lidar system 100. As an example, target 130 may include all or a portion of a person, vehicle, motorcycle, truck, train, bicycle, wheelchair, pedestrian, animal, road sign, traffic light, lane marking, road-surface marking, parking space, pylon, guard rail, traffic barrier, pothole, railroad crossing, obstacle in or near a road, curb, stopped vehicle on or beside a road, utility pole, house, building, trash can, mailbox, tree, any other suitable object, or any suitable combination of all or part of two or more objects. In particular embodiments, a target may be referred to as an object.

In particular embodiments, light source 110, scanner 120, and receiver 140 may be packaged together within a single housing, where a housing may refer to a box, case, or enclosure that holds or contains all or part of a lidar system 100. As an example, a lidar-system enclosure may contain a light source 110, mirror 115, scanner 120, and receiver 140 of a lidar system 100. Additionally, the lidar-system enclosure may include a controller 150. The lidar-system enclosure may also include one or more electrical connections for conveying electrical power or electrical signals to or from the enclosure. In particular embodiments, one or more components of a lidar system 100 may be located remotely from a lidar-system enclosure. As an example, all or part of light source 110 may be located remotely from a lidar-system enclosure, and pulses of light produced by the light source 110 may be conveyed to the enclosure via optical fiber. As another example, all or part of a controller 150 may be located remotely from a lidar-system enclosure.

In particular embodiments, light source 110 may include an eye-safe laser, or lidar system 100 may be classified as an eye-safe laser system or laser product. An eye-safe laser, laser system, or laser product may refer to a system that includes a laser with an emission wavelength, average power, peak power, peak intensity, pulse energy, beam size, beam divergence, exposure time, or scanned output beam such that emitted light from the system presents little or no possibility of causing damage to a person’s eyes. As an example, light source 110 or lidar system 100 may be classified as a Class 1 laser product (as specified by the 60825-1:2014 standard of the International Electrotechnical Commission (IEC)) or a Class I laser product (as specified by Title 21, Section 1040.10 of the United States Code of Federal Regulations (CFR)) that is safe under all conditions of normal use. In particular embodiments, lidar system 100 may be an eye-safe laser product (e.g., with a Class 1 or Class I classification) configured to operate at any suitable wavelength between approximately 900 nm and approximately 2100 nm. As an example, lidar system 100 may include a laser with an operating wavelength between approximately 1200 nm and approximately 1400 nm or between approximately 1400 nm and approximately 1600 nm, and the laser or the lidar system 100 may be operated in an eye-safe manner. As another example, lidar system 100 may be an eye-safe laser product that includes a scanned laser with an operating wavelength between approximately 900 nm and approximately 1700 nm. As another example, lidar system 100 may be a Class 1 or Class I laser product that includes a laser diode, fiber laser, or solid-state laser with an operating wavelength between approximately 1200 nm and approximately 1600 nm. As another example, lidar system 100 may have operating wavelengths between approximately 1500 nm and approximately 1550 nm.

In particular embodiments, one or more lidar systems 100 may be integrated into a vehicle. As an example, multiple lidar systems 100 may be integrated into a car to provide a complete 360-degree horizontal FOR around the car. As another example, 2-10 lidar systems 100, each system having a 45-degree to 180-degree horizontal FOR, may be combined together to form a sensing system that provides a point cloud covering a 360-degree horizontal FOR. The lidar systems 100 may be oriented so that adjacent FORs have an amount of spatial or angular overlap to allow data from the multiple lidar systems 100 to be combined or stitched together to form a single or continuous 360-degree point cloud. As an example, the FOR of each lidar system 100 may have approximately 1-30 degrees of overlap with an adjacent FOR. In particular embodiments, a vehicle may refer to a mobile machine configured to transport people or cargo. For example, a vehicle may include, may take the form of, or may be referred to as a car, automobile, motor vehicle, truck, bus, van, trailer, off-road vehicle, farm vehicle, lawn mower, construction equipment, forklift, robot, golf cart, motorhome, taxi, motorcycle, scooter, bicycle, skateboard, train, snowmobile, watercraft (e.g., a ship or boat), aircraft (e.g., a fixed-wing aircraft, helicopter, or dirigible), unmanned aerial vehicle (e.g., drone), or spacecraft. In particular embodiments, a vehicle may include an internal combustion engine or an electric motor that provides propulsion for the vehicle.

In particular embodiments, one or more lidar systems 100 may be included in a vehicle as part of an advanced driver assistance system (ADAS) to assist a driver of the vehicle in operating the vehicle. For example, a lidar system 100 may be part of an ADAS that provides information (e.g., about the surrounding environment) or feedback to a driver (e.g., to alert the driver to potential problems or hazards) or that automatically takes control of part of a vehicle (e.g., a braking system or a steering system) to avoid collisions or accidents. A lidar system 100 may be part of a vehicle ADAS that provides adaptive cruise control, automated braking, automated parking, collision avoidance, alerts the driver to hazards or other vehicles, maintains the vehicle in the correct lane, or provides a warning if an object or another vehicle is in a blind spot.

In particular embodiments, one or more lidar systems 100 may be integrated into a vehicle as part of an autonomous-vehicle driving system. As an example, a lidar system 100 may provide information about the surrounding environment to a driving system of an autonomous vehicle. An autonomous-vehicle driving system may be configured to guide the autonomous vehicle through an environment surrounding the vehicle and toward a destination. An autonomous-vehicle driving system may include one or more computing systems that receive information from a lidar system 100 about the surrounding environment, analyze the received information, and provide control signals to the vehicle’s driving systems (e.g., steering mechanism, accelerator, brakes, lights, or turn signals). As an example, a lidar system 100 integrated into an autonomous vehicle may provide an autonomous-vehicle driving system with a point cloud every 0.1 seconds (e.g., the point cloud has a 10 Hz update rate, representing 10 frames per second). The autonomous-vehicle driving system may analyze the received point clouds to sense or identify targets 130 and their respective locations, distances, or speeds, and the autonomous-vehicle driving system may update control signals based on this information. As an example, if lidar system 100 detects a vehicle ahead that is slowing down or stopping, the autonomous-vehicle driving system may send instructions to release the accelerator and apply the brakes.

In particular embodiments, an autonomous vehicle may be referred to as an autonomous car, driverless car, self-driving car, robotic car, or unmanned vehicle. In particular embodiments, an autonomous vehicle may refer to a vehicle configured to sense its environment and navigate or drive with little or no human input. As an example, an autonomous vehicle may be configured to drive to any suitable location and control or perform all safety-critical functions (e.g., driving, steering, braking, parking) for the entire trip, with the driver not expected to control the vehicle at any time. As another example, an autonomous vehicle may allow a driver to safely turn their attention away from driving tasks in particular environments (e.g., on freeways), or an autonomous vehicle may provide control of a vehicle in all but a few environments, requiring little or no input or attention from the driver.

In particular embodiments, an autonomous vehicle may be configured to drive with a driver present in the vehicle, or an autonomous vehicle may be configured to operate the vehicle with no driver present. As an example, an autonomous vehicle may include a driver’s seat with associated controls (e.g., steering wheel, accelerator pedal, and brake pedal), and the vehicle may be configured to drive with no one seated in the driver’s seat or with little or no input from a person seated in the driver’s seat. As another example, an autonomous vehicle may not include any driver’s seat or associated driver’s controls, and the vehicle may perform substantially all driving functions (e.g., driving, steering, braking, parking, and navigating) without human input. As another example, an autonomous vehicle may be configured to operate without a driver (e.g., the vehicle may be configured to transport human passengers or cargo without a driver present in the vehicle). As another example, an autonomous vehicle may be configured to operate without any human passengers (e.g., the vehicle may be configured for transportation of cargo without having any human passengers onboard the vehicle).

In particular embodiments, an optical signal (which may be referred to as a light signal, a light waveform, an optical waveform, an output beam, an emitted optical signal, or emitted light) may include pulses of light, CW light, amplitude-modulated light, frequency-modulated (FM) light, or any suitable combination thereof. Although this disclosure describes or illustrates example embodiments of lidar systems 100 or light sources 110 that produce optical signals that include pulses of light, the embodiments described or illustrated herein may also be applied, where appropriate, to other types of optical signals, including continuous-wave (CW) light, amplitude-modulated optical signals, or frequency-modulated optical signals. For example, a lidar system 100 as described or illustrated herein may be a pulsed lidar system and may include a light source 110 that produces pulses of light. Alternatively, a lidar system 100 may be configured to operate as a frequency-modulated continuous-wave (FMCW) lidar system and may include a light source 110 that produces CW light or a frequency-modulated optical signal.

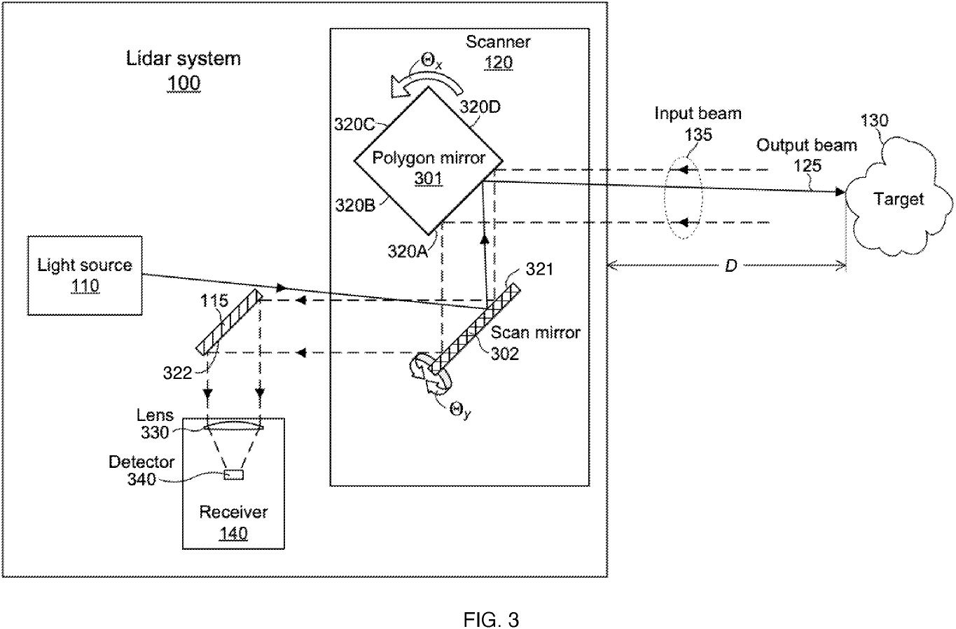

In particular embodiments, a lidar system 100 may be an FMCW lidar system where the emitted light from the light source 110 (e.g., output beam 125 in FIG. 1 or FIG. 3) includes frequency-modulated light. A pulsed lidar system is a type of lidar system 100 in which the light source 110 emits pulses of light, and the distance to a remote target 130 is determined based on the round-trip time-of-flight for a pulse of light to travel to the target 130 and back. Another type of lidar system 100 is a frequency-modulated lidar system, which may be referred to as a frequency-modulated continuous-wave (FMCW) lidar system. An FMCW lidar system uses frequency-modulated light to determine the distance to a remote target 130 based on a frequency of received light (which includes emitted light scattered by the remote target) relative to a frequency of local-oscillator (LO) light. A round-trip time for the emitted light to travel to a target 130 and back to the lidar system may correspond to a frequency difference between the received scattered light and the LO light. A larger frequency difference may correspond to a longer round-trip time and a greater distance to the target 130.

A light source 110 for an FMCW lidar system may include at least one instance of (i) a direct-emitter laser diode, (ii) a seed laser diode followed by an SOA, (iii) a seed laser diode followed by a fiber-optic amplifier, or (iv) a seed laser diode followed by an SOA and then a fiber-optic amplifier. A seed laser diode or a direct-emitter laser diode may be operated in a CW manner (e.g., by driving the laser diode with a substantially constant DC current), and a frequency modulation may be provided by an external modulator (e.g., an electro-optic phase modulator may apply a frequency modulation to seed-laser light). Alternatively, a frequency modulation may be produced by applying a current modulation to a seed laser diode or a direct-emitter laser diode. The current modulation (which may be provided along with a DC bias current) may produce a corresponding refractive-index modulation in the laser diode, which results in a frequency modulation of the light emitted by the laser diode. The current-modulation component (and the corresponding frequency modulation) may have any suitable frequency or shape (e.g., piecewise linear, sinusoidal, triangle-wave, or sawtooth). For example, the current-modulation component (and the resulting frequency modulation of the emitted light) may increase or decrease monotonically over a particular time interval. As another example, the current-modulation component may include a triangle or sawtooth wave with an electrical current that increases or decreases linearly over a particular time interval, and the light emitted by the laser diode may include a corresponding frequency modulation in which the optical frequency increases or decreases approximately linearly over the particular time interval. For example, a light source 110 that emits light with a linear frequency change of 200 MHz over a 2-µs time interval may be referred to as having a frequency modulation m of 10¹⁴ Hz/s (or, 100 MHz/µs)

In addition to producing frequency-modulated emitted light, a light source 110 may also produce frequency-modulated local-oscillator (LO) light. The LO light may be coherent with the emitted light, and the frequency modulation of the LO light may match that of the emitted light. The LO light may be produced by splitting off a portion of the emitted light prior to the emitted light exiting the lidar system. Alternatively, the LO light may be produced by a seed laser diode or a direct-emitter laser diode that is part of the light source 110. For example, the LO light may be emitted from the back facet of a seed laser diode or a direct-emitter laser diode, or the LO light may be split off from the seed light emitted from the front facet of a seed laser diode. The received light (e.g., emitted light that is scattered by a target 130) and the LO light may each be frequency modulated, with a frequency difference or offset that corresponds to the distance to the target 130. For a linearly chirped light source (e.g., a frequency modulation that produces a linear change in frequency with time), the larger the frequency difference is between the received light and the LO light, the farther away the target 130 is located.

A frequency difference between received light and LO light may be determined by mixing the received light with the LO light (e.g., by coupling the two beams onto a detector so they are coherently mixed together at the detector) and determining the resulting beat frequency. For example, a photocurrent signal produced by an APD may include a beat signal resulting from the coherent mixing of the received light and the LO light, and a frequency of the beat signal may correspond to the frequency difference between the received light and the LO light. The photocurrent signal from an APD (or a voltage signal that corresponds to the photocurrent signal) may be analyzed using a frequency-analysis technique (e.g., a fast Fourier transform (FFT) technique) to determine the frequency of the beat signal. If a linear frequency modulation m (e.g., in units of Hz/s) is applied to a CW laser, then the round-trip time T may be related to the frequency difference Δfbetween the received scattered light and the LO light by the expression T=Δf/m. Additionally, the distance D from the target 130 to the lidar system 100 may be expressed as D=(Δf/m)·c/2, where c is the speed of light. For example, for a light source 110 with a linear frequency modulation of 10¹⁴ Hz/s, if a frequency difference (between the received scattered light and the LO light) of 33 MHz is measured, then this corresponds to a round-trip time of approximately 330 ns and a distance to the target of approximately 50 meters. As another example, a frequency difference of 133 MHz corresponds to a round-trip time of approximately 1.33 µs and a distance to the target of approximately 200 meters. A receiver or processor of an FMCW lidar system may determine a frequency difference between received scattered light and LO light, and the distance to a target may be determined based on the frequency difference. The frequency difference Δfbetween received scattered light and LO light corresponds to the round-trip time T (e.g., through the relationship T=Δf/m), and determining the frequency difference may correspond to or may be referred to as determining the round-trip time.

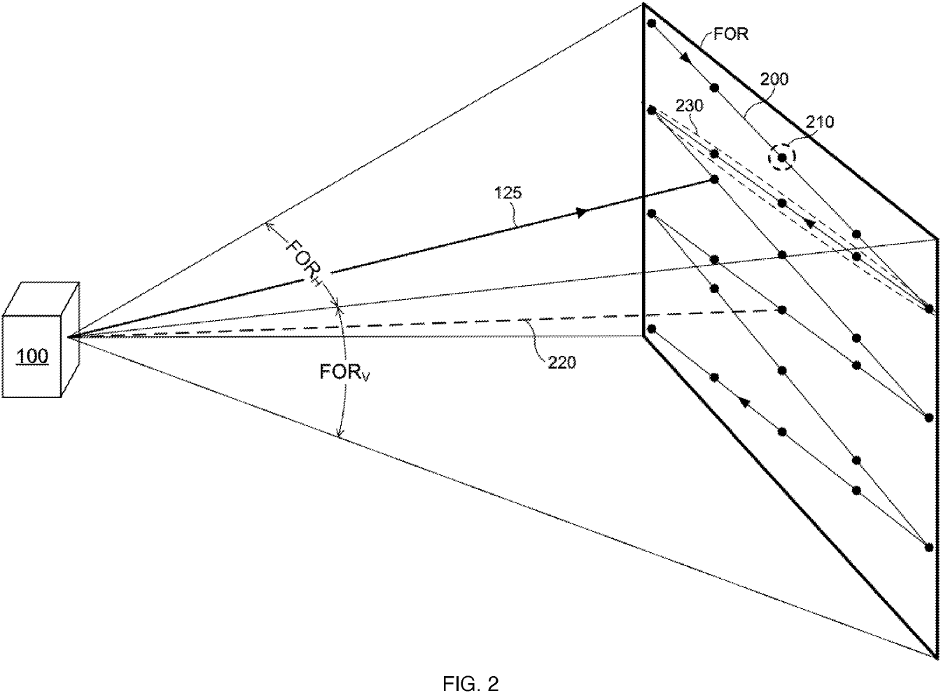

FIG. 2 illustrates an example scan pattern 200 produced by a lidar system 100. A scanner 120 of the lidar system 100 may scan the output beam 125 (which may include multiple emitted optical signals) along a scan pattern 200 that is contained within a field of regard (FOR) of the lidar system 100. A scan pattern 200 (which may be referred to as an optical scan pattern, optical scan path, scan path, or scan) may represent a path or course followed by output beam 125 as it is scanned across all or part of a FOR. Each traversal of a scan pattern 200 may correspond to the capture of a single frame or a single point cloud. In particular embodiments, a lidar system 100 may be configured to scan output optical beam 125 along one or more particular scan patterns 200. In particular embodiments, a scan pattern 200 may scan across any suitable field of regard (FOR) having any suitable horizontal FOR (FOR_{H}) and any suitable vertical FOR (FORv). For example, a scan pattern 200 may have a field of regard represented by angular dimensions (e.g., FOR_{H} × FORv) 40°×30°, 90°×40°, or 60°×15°. As another example, a scan pattern 200 may have a FOR_{H} greater than or equal to 10°, 25°, 30°, 40°, 60°, 90°, or 120°. As another example, a scan pattern 200 may have a FORv greater than or equal to 2°, 5°, 10°, 15°, 20°, 30°, or 45°.

In the example of FIG. 2, reference line 220 represents a center of the field of regard of scan pattern 200. In particular embodiments, reference line 220 may have any suitable orientation, such as for example, a horizontal angle of 0° (e.g., reference line 220 may be oriented straight ahead) and a vertical angle of 0° (e.g., reference line 220 may have an inclination of 0°), or reference line 220 may have a nonzero horizontal angle or a nonzero inclination (e.g., a vertical angle of +10° or -10°). In FIG. 2, if the scan pattern 200 has a 60°× 15° field of regard, then scan pattern 200 covers a ±30° horizontal range with respect to reference line 220 and a ±7.5° vertical range with respect to reference line 220. Additionally, optical beam 125 in FIG. 2 has an orientation of approximately -15° horizontal and +3° vertical with respect to reference line 220. Optical beam 125 may be referred to as having an azimuth of -15° and an altitude of +3° relative to reference line 220. In particular embodiments, an azimuth (which may be referred to as an azimuth angle) may represent a horizontal angle with respect to reference line 220, and an altitude (which may be referred to as an altitude angle, elevation, or elevation angle) may represent a vertical angle with respect to reference line 220.

In particular embodiments, a scan pattern 200 may include multiple pixels 210, and each pixel 210 may be associated with one or more laser pulses or one or more distance measurements. Additionally, a scan pattern 200 may include multiple scan lines 230, where each scan line represents one scan across at least part of a field of regard, and each scan line 230 may include multiple pixels 210. In FIG. 2, scan line 230 includes five pixels 210 and corresponds to an approximately horizontal scan across the FOR from right to left, as viewed from the lidar system 100. In particular embodiments, a cycle of scan pattern 200 may include a total of Pₓ×P_{y} pixels 210 (e.g., a two-dimensional distribution of Pₓ by P_{y} pixels). As an example, scan pattern 200 may include a distribution with dimensions of approximately 100-2,000 pixels 210 along a horizontal direction and approximately 4-400 pixels 210 along a vertical direction. As another example, scan pattern 200 may include a distribution of 1,000 pixels 210 along the horizontal direction by 64 pixels 210 along the vertical direction (e.g., the frame size is 1000×64 pixels) for a total of 64,000 pixels per cycle of scan pattern 200. In particular embodiments, the number of pixels 210 along a horizontal direction may be referred to as a horizontal resolution of scan pattern 200, and the number of pixels 210 along a vertical direction may be referred to as a vertical resolution. As an example, scan pattern 200 may have a horizontal resolution of greater than or equal to 100 pixels 210 and a vertical resolution of greater than or equal to 4 pixels 210. As another example, scan pattern 200 may have a horizontal resolution of 100-2,000 pixels 210 and a vertical resolution of 4-400 pixels 210.

In particular embodiments, a pixel 210 may refer to a data element that includes (i) distance information (e.g., a distance from a lidar system 100 to a target 130 from which an associated pulse of light was scattered) or (ii) an elevation angle and an azimuth angle associated with the pixel (e.g., the elevation and azimuth angles along which the associated pulse of light was emitted). Each pixel 210 may be associated with a distance (e.g., a distance to a portion of a target 130 from which an associated laser pulse was scattered) or one or more angular values. As an example, a pixel 210 may be associated with a distance value and two angular values (e.g., an azimuth and altitude) that represent the angular location of the pixel 210 with respect to the lidar system 100. A distance to a portion of target 130 may be determined based at least in part on a time-of-flight measurement for a corresponding pulse. An angular value (e.g., an azimuth or altitude) may correspond to an angle (e.g., relative to reference line 220) of output beam 125 (e.g., when a corresponding pulse is emitted from lidar system 100) or an angle of input beam 135 (e.g., when an input signal is received by lidar system 100). In particular embodiments, an angular value may be determined based at least in part on a position of a component of scanner 120. As an example, an azimuth or altitude value associated with a pixel 210 may be determined from an angular position of one or more corresponding scanning mirrors of scanner 120.

FIG. 3 illustrates an example lidar system 100 with an example rotating polygon mirror 301. In particular embodiments, a scanner 120 may include a polygon mirror 301 configured to scan output beam 125 along a particular direction. Although not shown in FIG. 3, when outputting light pulses as part of output beam 125, lidar system 100 can include pulse-energy measurement circuitry as disclosed herein used to determine the pulse energy associated with individual output light pulses. In the example of FIG. 3, scanner 120 includes two scanning mirrors: (1) a polygon mirror 301 that rotates along the Oₓ direction and (2) a scanning mirror 302 that oscillates back and forth along the O_{y} direction. The output beam 125 from light source 110, which passes alongside mirror 115, is reflected by reflecting surface 321 of scan mirror 302 and is then reflected by a reflecting surface (e.g., surface 320A, 320B, 320C, or 320D) of polygon mirror 301. Scattered light from a target 130 returns to the lidar system 100 as input beam 135. The input beam 135 reflects from polygon mirror 301, scan mirror 302, and mirror 115, which directs input beam 135 through focusing lens 330 and to the detector 340 of receiver 140. As shown in FIG. 3, scan mirror 302 includes reflecting surface 321 and mirror 115 includes reflecting surface 322. The detector 340 may be a PN photodiode, a PIN photodiode, an APD, an SPAD, or any other suitable detector. A reflecting surface 320 (which may be referred to as a reflective surface) may include a reflective metallic coating (e.g., gold, silver, or aluminum) or a reflective dielectric coating, and the reflecting surface 320 may have any suitable reflectivity R at an operating wavelength of the light source 110 (e.g., R greater than or equal to 70%, 80%, 90%, 95%, 98%, or 99%).

In particular embodiments, a polygon mirror 301 may be configured to rotate along a Oₓ or O_{y} direction and scan output beam 125 along a substantially horizontal or vertical direction, respectively. A rotation along a Oₓ direction may refer to a rotational motion of mirror 301 that results in output beam 125 scanning along a substantially horizontal direction. Similarly, a rotation along a O_{y} direction may refer to a rotational motion that results in output beam 125 scanning along a substantially vertical direction. In FIG. 3, mirror 301 is a polygon mirror that rotates along the Oₓ direction and scans output beam 125 along a substantially horizontal direction, and mirror 302 pivots along the O_{y} direction and scans output beam 125 along a substantially vertical direction. In particular embodiments, a polygon mirror 301 may be configured to scan output beam 125 along any suitable direction. As an example, a polygon mirror 301 may scan output beam 125 at any suitable angle with respect to a horizontal or vertical direction, such as for example, at an angle of approximately 0°, 10°, 20°, 30°, 45°, 60°, 70°, 80°, or 90° with respect to a horizontal or vertical direction.

In particular embodiments, a polygon mirror 301 may refer to a multi-sided object having reflective surfaces 320 on two or more of its sides or faces. As an example, a polygon mirror may include any suitable number of reflective faces (e.g., 2, 3, 4, 5, 6, 7, 8, or 10 faces), where each face includes a reflective surface 320. A polygon mirror 301 may have a cross-sectional shape of any suitable polygon, such as for example, a triangle (with three reflecting surfaces 320), square (with four reflecting surfaces 320), pentagon (with five reflecting surfaces 320), hexagon (with six reflecting surfaces 320), heptagon (with seven reflecting surfaces 320), or octagon (with eight reflecting surfaces 320). In FIG. 3, the polygon mirror 301 has a substantially square cross-sectional shape and four reflecting surfaces (320A, 320B, 320C, and 320D). The polygon mirror 301 in FIG. 3 may be referred to as a square mirror, a cube mirror, or a four-sided polygon mirror. In FIG. 3, the polygon mirror 301 may have a shape similar to a cube, cuboid, or rectangular prism. Additionally, the polygon mirror 301 may have a total of six sides, where four of the sides include faces with reflective surfaces (320A, 320B, 320C, and 320D).

In particular embodiments, a polygon mirror 301 may be continuously rotated in a clockwise or counter-clockwise rotation direction about a rotation axis of the polygon mirror 301. The rotation axis may correspond to a line that is perpendicular to the plane of rotation of the polygon mirror 301 and that passes through the center of mass of the polygon mirror 301. In FIG. 3, the polygon mirror 301 rotates in the plane of the drawing, and the rotation axis of the polygon mirror 301 is perpendicular to the plane of the drawing. An electric motor may be configured to rotate a polygon mirror 301 at a substantially fixed frequency (e.g., a rotational frequency of approximately 1 Hz (or 1 revolution per second), 10 Hz, 50 Hz, 100 Hz, 500 Hz, or 1,000 Hz). As an example, a polygon mirror 301 may be mechanically coupled to an electric motor (e.g., a synchronous electric motor) which is configured to spin the polygon mirror 301 at a rotational speed of approximately 160 Hz (or, 9600 revolutions per minute (RPM)).

In particular embodiments, output beam 125 may be reflected sequentially from the reflective surfaces 320A, 320B, 320C, and 320D as the polygon mirror 301 is rotated. This results in the output beam 125 being scanned along a particular scan axis (e.g., a horizontal or vertical scan axis) to produce a sequence of scan lines, where each scan line corresponds to a reflection of the output beam 125 from one of the reflective surfaces of the polygon mirror 301. In FIG. 3, the output beam 125 reflects off of reflective surface 320A to produce one scan line. Then, as the polygon mirror 301 rotates, the output beam 125 reflects off of reflective surfaces 320B, 320C, and 320D to produce a second, third, and fourth respective scan line. In particular embodiments, a lidar system 100 may be configured so that the output beam 125 is first reflected from polygon mirror 301 and then from scan mirror 302 (or vice versa). As an example, an output beam 125 from light source 110 may first be directed to polygon mirror 301, where it is reflected by a reflective surface of the polygon mirror 301, and then the output beam 125 may be directed to scan mirror 302, where it is reflected by reflective surface 321 of the scan mirror 302. In the example of FIG. 3, the output beam 125 is reflected from the polygon mirror 301 and the scan mirror 302 in the reverse order. In FIG. 3, the output beam 125 from light source 110 is first directed to the scan mirror 302, where it is reflected by reflective surface 321, and then the output beam 125 is directed to the polygon mirror 301, where it is reflected by reflective surface 320A.

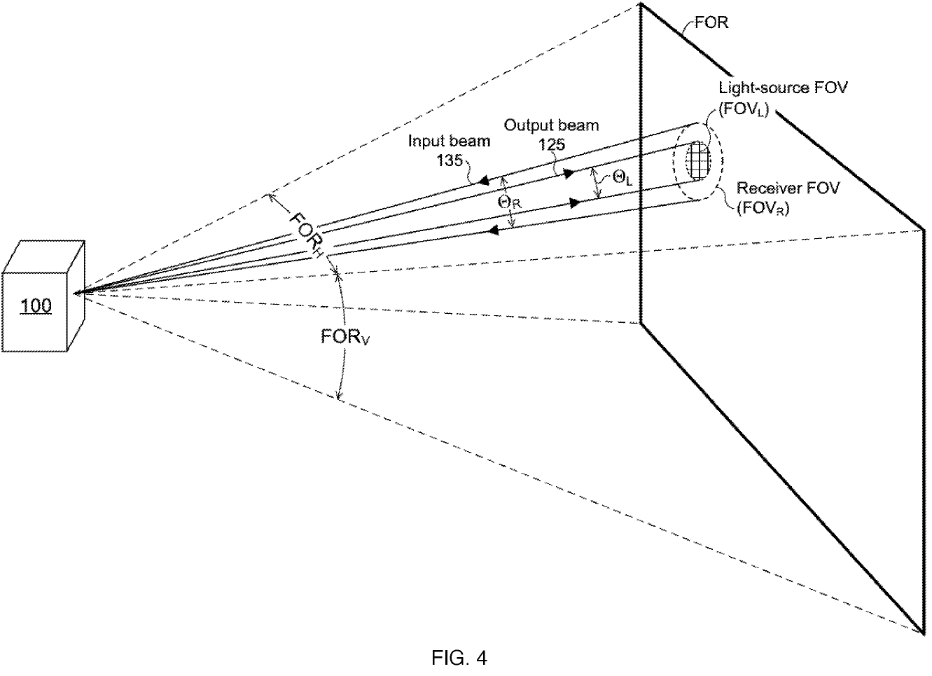

FIG. 4 illustrates an example light-source field of view (FOV_{L}) and receiver field of view (FOV_{R}) for a lidar system 100. A light source 110 of lidar system 100 may emit pulses of light as the FOV_{L} and FOV_{R} are scanned by scanner 120 across a field of regard (FOR). In particular embodiments, a light-source field of view may refer to an angular cone illuminated by the light source 110 at a particular instant of time. Similarly, a receiver field of view may refer to an angular cone over which the receiver 140 may receive or detect light at a particular instant of time, and any light outside the receiver field of view may not be received or detected. As an example, as the light-source field of view is scanned across a field of regard, a portion of a pulse of light emitted by the light source 110 may be sent downrange from lidar system 100, and the pulse of light may be sent in the direction that the FOV_{L} is pointing at the time the pulse is emitted. The pulse of light may scatter off a target 130, and the receiver 140 may receive and detect a portion of the scattered light that is directed along or contained within the FOV_{R}.

In particular embodiments, scanner 120 may be configured to scan both a light-source field of view and a receiver field of view across a field of regard of the lidar system 100. Multiple pulses of light may be emitted and detected as the scanner 120 scans the FOV_{L} and FOV_{R} across the field of regard of the lidar system 100 while tracing out a scan pattern 200. In particular embodiments, the light-source field of view and the receiver field of view may be scanned synchronously with respect to one another, so that as the FOV_{L} is scanned across a scan pattern 200, the FOV_{R} follows substantially the same path at the same scanning speed. Additionally, the FOV_{L} and FOV_{R} may maintain the same relative position to one another as they are scanned across the field of regard. As an example, the FOV_{L} may be substantially overlapped with or centered inside the FOV_{R} (as illustrated in FIG. 4), and this relative positioning between FOV_{L} and FOV_{R} may be maintained throughout a scan. As another example, the FOV_{R} may lag behind the FOV_{L} by a particular, fixed amount throughout a scan (e.g., the FOV_{R} may be offset from the FOV_{L} in a direction opposite the scan direction).

In particular embodiments, the FOV_{L} may have an angular size or extent O_{L} that is substantially the same as or that corresponds to the divergence of the output beam 125, and the FOV_{R} may have an angular size or extent O_{R} that corresponds to an angle over which the receiver 140 may receive and detect light. In particular embodiments, the receiver field of view may be any suitable size relative to the light-source field of view. As an example, the receiver field of view may be smaller than, substantially the same size as, or larger than the angular extent of the light-source field of view. In particular embodiments, the light-source field of view may have an angular extent of less than or equal to 50 milliradians, and the receiver field of view may have an angular extent of less than or equal to 50 milliradians. The FOV_{L} may have any suitable angular extent O_{L}, such as for example, approximately 0.1 mrad, 0.2 mrad, 0.5 mrad, 1 mrad, 1.5 mrad, 2 mrad, 3 mrad, 5 mrad, 10 mrad, 20 mrad, 40 mrad, or 50 mrad. Similarly, the FOV_{R} may have any suitable angular extent O_{R}, such as for example, approximately 0.1 mrad, 0.2 mrad, 0.5 mrad, 1 mrad, 1.5 mrad, 2 mrad, 3 mrad, 5 mrad, 10 mrad, 20 mrad, 40 mrad, or 50 mrad. In particular embodiments, the light-source field of view and the receiver field of view may have approximately equal angular extents. As an example, O_{L} and O_{R} may both be approximately equal to 1 mrad, 2 mrad, or 4 mrad. In particular embodiments, the receiver field of view may be larger than the light-source field of view, or the light-source field of view may be larger than the receiver field of view. As an example, O_{L} may be approximately equal to 3 mrad, and O_{R} may be approximately equal to 4 mrad. As another example, O_{R} may be approximately L times larger than O_{L}, where L is any suitable factor, such as for example, 1.1, 1.2, 1.5, 2, 3, 5, or 10.

In particular embodiments, a pixel 210 may represent or may correspond to a light-source field of view or a receiver field of view. As the output beam 125 propagates from the light source 110, the diameter of the output beam 125 (as well as the size of the corresponding pixel 210) may increase according to the beam divergence O_{L}. As an example, if the output beam 125 has a O_{L} of 2 mrad, then at a distance of 100 m from the lidar system 100, the output beam 125 may have a size or diameter of approximately 20 cm, and a corresponding pixel 210 may also have a corresponding size or diameter of approximately 20 cm. At a distance of 200 m from the lidar system 100, the output beam 125 and the corresponding pixel 210 may each have a diameter of approximately 40 cm.

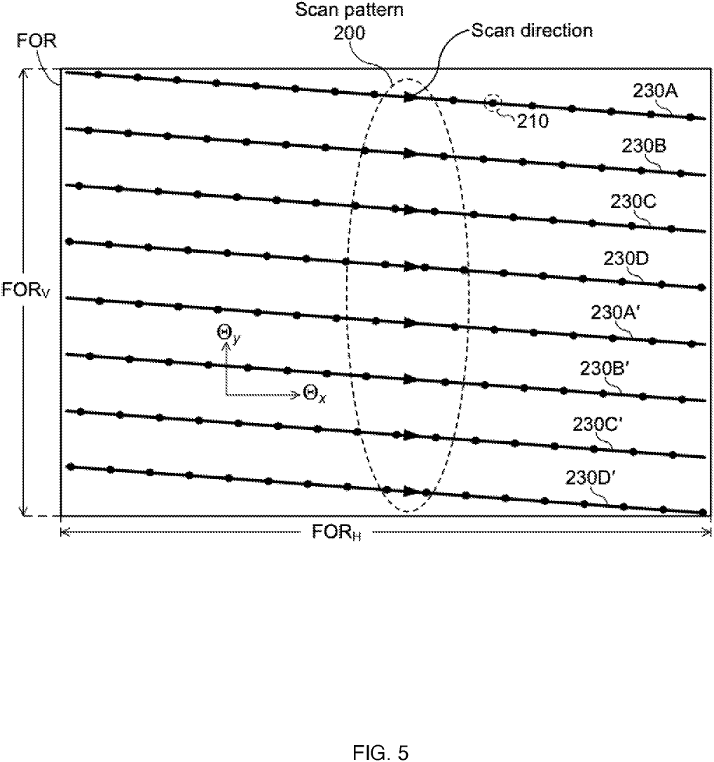

FIG. 5 illustrates an example unidirectional scan pattern 200 that includes multiple pixels 210 and multiple scan lines 230. In particular embodiments, scan pattern 200 may include any suitable number of scan lines 230 (e.g., approximately 1, 2, 5, 10, 20, 50, 100, 500, or 1,000 scan lines), and each scan line 230 of a scan pattern 200 may include any suitable number of pixels 210 (e.g., 1, 2, 5, 10, 20, 50, 100, 200, 500, 1,000, 2,000, or 5,000 pixels). The scan pattern 200 illustrated in FIG. 5 includes eight scan lines 230, and each scan line 230 includes approximately 16 pixels 210. In particular embodiments, a scan pattern 200 where the scan lines 230 are scanned in two directions (e.g., alternately scanning from right to left and then from left to right) may be referred to as a bidirectional scan pattern 200, and a scan pattern 200 where the scan lines 230 are scanned in the same direction may be referred to as a unidirectional scan pattern 200. The scan pattern 200 in FIG. 2 may be referred to as a bidirectional scan pattern, and the scan pattern 200 in FIG. 5 may be referred to as a unidirectional scan pattern 200 where each scan line 230 travels across the FOR in substantially the same direction (e.g., approximately from left to right as viewed from the lidar system 100). In particular embodiments, scan lines 230 of a unidirectional scan pattern 200 may be directed across a FOR in any suitable direction, such as for example, from left to right, from right to left, from top to bottom, from bottom to top, or at any suitable angle (e.g., at a 0°, 5°, 10°, 30°, or 45° angle) with respect to a horizontal or vertical axis. In particular embodiments, each scan line 230 in a unidirectional scan pattern 200 may be a separate line that is not directly connected to a previous or subsequent scan line 230.

In particular embodiments, a unidirectional scan pattern 200 may be produced by a scanner 120 that includes a polygon mirror (e.g., polygon mirror 301 of FIG. 3), where each scan line 230 is associated with a particular reflective surface 320 of the polygon mirror. As an example, reflective surface 320A of polygon mirror 301 in FIG. 3 may produce scan line 230A in FIG. 5. Similarly, as the polygon mirror 301 rotates, reflective surfaces 320B, 320C, and 320D may successively produce scan lines 230B, 230C, and 230D, respectively. Additionally, for a subsequent revolution of the polygon mirror 301, the scan lines 230A', 230B', 230C', and 230D' may be successively produced by reflections of the output beam 125 from reflective surfaces 320A, 320B, 320C, and 320D, respectively. In particular embodiments, N successive scan lines 230 of a unidirectional scan pattern 200 may correspond to one full revolution of an N-sided polygon mirror. As an example, the four scan lines 230A, 230B, 230C, and 230D in FIG. 5 may correspond to one full revolution of the four-sided polygon mirror 301 in FIG. 3. Additionally, a subsequent revolution of the polygon mirror 301 may produce the next four scan lines 230A', 230B', 230C', and 230D' in FIG. 5.

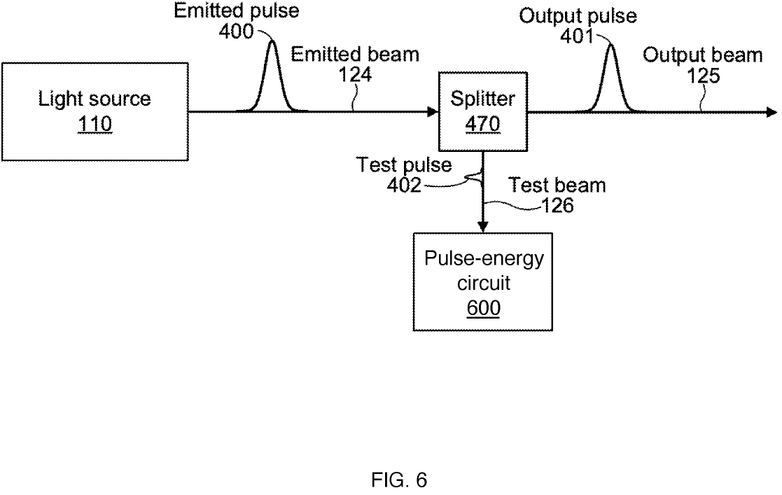

FIG. 6 illustrates an example light source, optical splitter, and pulse-energy measurement circuit. In the example shown, FIG. 6 includes components light source 110, splitter 470, and pulse-energy circuit 600 that are integrated into a lidar system, such as lidar system 100 of FIGS. 1-4, for performing pulse-energy measurements. For example, using at least in part the components of FIG. 6 and a processor and/or controller of the lidar system, individual light pulses outputted by the corresponding lidar system can be measured for their corresponding pulse energy. In some embodiments, light source 110 is light source 110 of FIG. 1 and/or 3 and output beam 125 is output beam 125 of FIGS. 1-4.

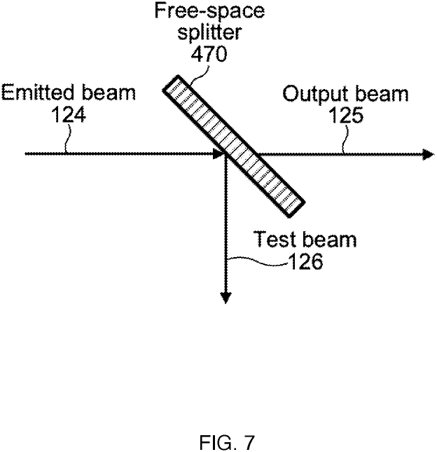

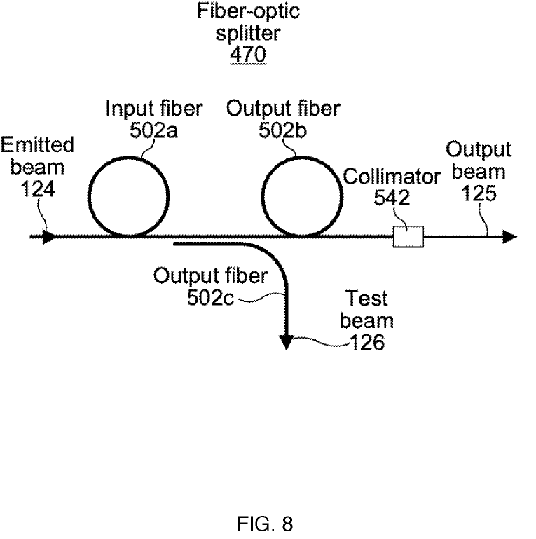

As shown in the example of FIG. 6, light source 110 outputs emitted beam 124. In the particular application of light source 110, emitted beam 124 outputs a light pulse as emitted pulse 400. Splitter 470 receives emitted beam 124 and splits the beam into output beam 125 and test beam 126. Output beam 125 includes output pulse 401 and test beam 126 includes test pulse 402. In various embodiments, splitter 470 is configured to split emitted beam 124 into output beam 125 and test beam 126 following a particular split ratio. Once emitted beam 124 is split by splitter 470, test beam 126 is received at pulse-energy circuit 600 and output beam 125 is directed towards other components of the lidar system, such as scanner 120 of FIG. 1. In various embodiments, pulse-energy circuit 600 receives test beam 126 as a test pulse 402. Pulse-energy circuit 600 is a pulse-energy measurement module and includes pulse-energy measurement circuitry used at least in part to determine the individual pulse energy of test pulse 402. Pulse-energy circuit 600 can output one or more numerical values corresponding to the energy of test pulse 402. In various embodiments, the pulse energy of test pulse 402 corresponds to and is used to determine the pulse energy of output pulse 401. For example, the energy of the output pulse 401 represented using the term (Eo) is determined from an expression Eo = E_{T}/f, wherein E_{T} is the energy of the test pulse 402, and f is a split ratio of the splitter 470. In various embodiments, splitter 470 can be a free-space splitter as shown in FIG. 7, a fiber-optic splitter as shown in FIG. 8, and/or another appropriate splitter meeting the required split ratio.

In some embodiments, splitter 470 is an optical splitter and is configured to split emitted beam 124 so that the energy of test pulse 402 and output pulse 401 meet particular energy requirements with respect to emitted pulse 400. For example, in some embodiments, emitted beam 124 is split so that the energy of test pulse 402 is less than or equal to 2% of the energy of emitted pulse 400 and the energy of output pulse 401 is greater than or equal to 98% of the energy of emitted pulse 400. In some embodiments, splitter 470 is a free-space optical splitter, an integrated-optic splitter, a fiber-optic splitter, or another appropriate type of optical splitter capable of meeting the particular energy requirements when splitting emitted beam 124.

FIG. 7 illustrates an example free-space optical splitter. In the example shown, free-space splitter 470 is an example embodiment of splitter 470 of FIG. 6. As shown in FIG. 7, free-space splitter 470 splits emitted beam 124 into output beam 125 and test beam 126. In various embodiments, emitted beam 124, output beam 125, and test beam 126 can be light pulses, such as light pulses generated from light source 110 of FIGS. 1, 3, and/or 6. In various embodiments, test beam 126 is directed to a pulse-energy circuit such as pulse-energy circuit 600 of FIG. 6. In particular embodiments, free-space splitter 470 can be implemented using one or more prisms and/or mirrors.

FIG. 8 illustrates an example fiber-optic splitter. In the example shown, fiber-optic splitter 470 is an example fiber-optic embodiment of splitter 470 of FIG. 6. As shown in FIG. 8, fiber-optic splitter 470 includes input fiber 502a, output fiber 502b, output fiber 502c, and collimator 542. In the context of fiber-optic splitter 470, emitted beam 124 is transmitted via input fiber 502a and is split between output fiber 502b and output fiber 502c. Output fiber 502b is connected to collimator 542, which outputs the received light beam as output beam 125. Output fiber 502c transmits the split portion of emitted beam 124 as test beam 126. In various embodiments, test beam 126 is directed to a pulse-energy circuit such as pulse-energy circuit 600 of FIG. 6. In various embodiments, emitted beam 124, output beam 125, and test beam 126 can be light pulses, such as light pulses generated from light source 110 of FIGS. 1, 3, and/or 6.

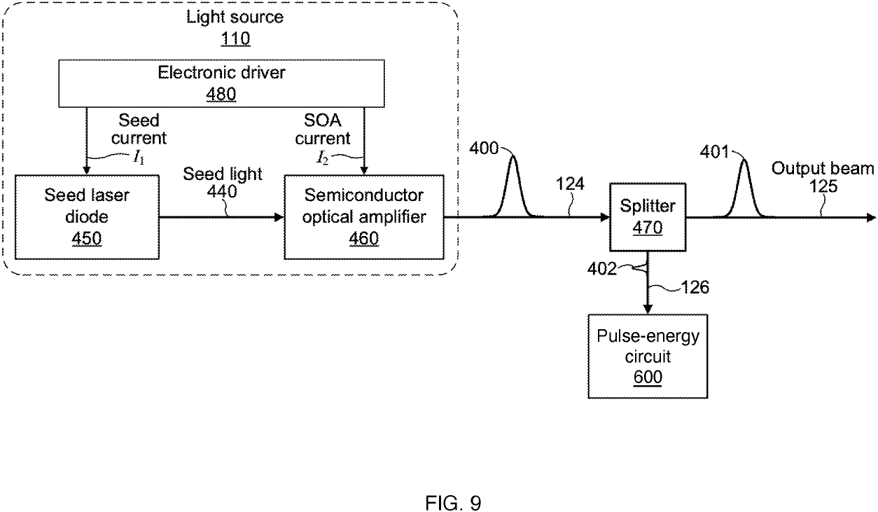

FIG. 9 illustrates an example light source, optical splitter, and pulse-energy measurement circuit, where the light source includes a seed laser diode and a semiconductor optical amplifier (SOA). In the example shown, FIG. 9 includes an embodiment of a light source 110 that includes seed laser diode 450, semiconductor optical amplifier (SOA) 460, and electronic driver 480. In various embodiments, electronic driver 480 provides seed current I₁ to seed laser diode 450 and semiconductor optical amplifier (SOA) current 1₂ to semiconductor optical amplifier (SOA) 460 at least in part to generate emitted beam 124. Within light source 110, seed laser diode 450 outputs seed light 440, which is amplified by semiconductor optical amplifier (SOA) 460. Light source 110 outputs emitted beam 124 to splitter 470. Splitter 470 splits emitted beam 124 into output beam 125 and test beam 126. Test beam 126 is directed to pulse-energy circuit 600. As shown in FIG. 9, emitted beam 124, output beam 125, and test beam 126 include corresponding light pulses emitted pulse 400, output pulse 401, and test pulse 402, respectively. In various embodiments, the components of FIG. 9 are integrated into a lidar system, such as lidar system 100 of FIGS. 1-4, for performing pulse-energy measurements and light source 110 is light source 110 of FIGS. 1, 3 and/or 6 and output beam 125 is output beam 125 of FIGS. 1-4 and 6-8. In some embodiments, splitter 470 is splitter 470 of FIGS. 6, 7, and/or 8 and pulse-energy circuit 600 is pulse-energy circuit 600 of FIG. 6. Similarly, emitted beam 124 and emitted pulse 400 are emitted beam 124 and emitted pulse 400 of FIG. 6, output beam 125 and output pulse 401 are output beam 125 and output pulse 401 of FIG. 6, and test beam 126 and test pulse 402 are test beam 126 and test pulse 402 of FIG. 6.

In the example of FIG. 9, light source 110 includes seed laser diode 450 and semiconductor optical amplifier (SOA) 460 that are driven by electronic driver 480 to generate light pulses such as emitted pulse 400. As described with respect to FIG. 6, emitted pulse 400 is split by splitter 470 to create test pulse 402 that can be measured by pulse-energy circuit 600. In some embodiments, pulse-energy circuit 600 outputs a numerical value corresponding to the energy of test pulse 402. A processor and/or controller of the lidar system determines the individual pulse energy amount of test pulse 402 based on the determined numerical value provided by pulse-energy circuit 600. By the relationship between output pulse 401 and test pulse 402, the pulse energy of output pulse 401 is also determined. In various embodiments, the output pulse measurement can be used to modify the operating parameters of light source 110, such as powering up or down light source 110 and/or its components.

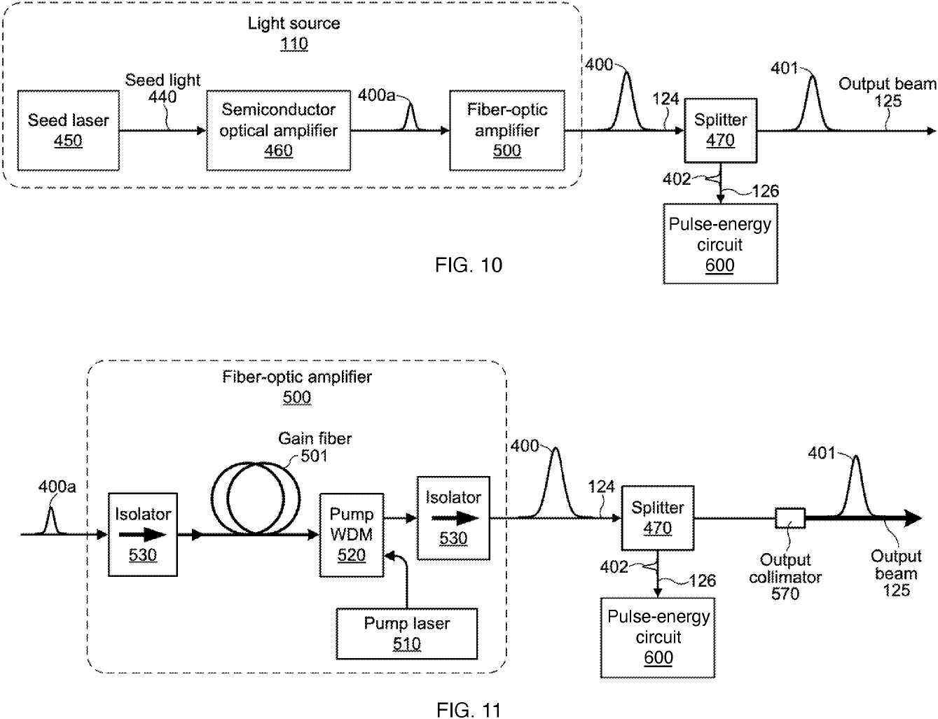

FIG. 10 illustrates an example light source, optical splitter, and pulse-energy measurement circuit, where the light source includes a seed laser diode, a semiconductor optical amplifier (SOA), and a fiber-optic amplifier. The example of FIG. 10 is similar to the example of FIG. 9 but displays a different embodiment of light source 110. In the example shown, FIG. 10 includes an embodiment of a light source 110 that includes seed laser diode 450, semiconductor optical amplifier (SOA) 460, and fiber-optic amplifier 500. Within light source 110, seed laser diode 450 outputs seed light 440, which is amplified by semiconductor optical amplifier (SOA) 460 as SOA amplified light pulse 400a. Fiber-optic amplifier 500 amplifies SOA amplified light pulse 400a and as a result light source 110 outputs emitted beam 124, which includes emitted pulse 400, to splitter 470. Splitter 470 splits emitted beam 124 into output beam 125 and test beam 126. Test beam 126 is directed to pulse-energy circuit 600. Similar to the example of FIG. 9, in FIG. 10, emitted beam 124, output beam 125, and test beam 126 include corresponding light pulses emitted pulse 400, output pulse 401, and test pulse 402, respectively. In various embodiments, the components of FIG. 10 are integrated into a lidar system, such as lidar system 100 of FIGS. 1-4, for performing pulse-energy measurements and light source 110 is light source 110 of FIGS. 1, 3 and/or 6 and output beam 125 is output beam 125 of FIGS. 1-4 and 6-8. In some embodiments, splitter 470 is splitter 470 of FIGS. 6, 7, and/or 8 and pulse-energy circuit 600 is pulse-energy circuit 600 of FIG. 6. Similarly, emitted beam 124 and emitted pulse 400 are emitted beam 124 and emitted pulse 400 of FIG. 6, output beam 125 and output pulse 401 are output beam 125 and output pulse 401 of FIG. 6, and test beam 126 and test pulse 402 are test beam 126 and test pulse 402 of FIG. 6.

In the example of FIG. 10, light source 110 includes seed laser diode 450, semiconductor optical amplifier (SOA) 460, and fiber-optic amplifier 500 to generate light pulses such as emitted pulse 400. As described with respect to FIGS. 6 and 9, emitted pulse 400 is split by splitter 470 to create test pulse 402 that can be measured by pulse-energy circuit 600. In some embodiments, pulse-energy circuit 600 outputs a numerical value corresponding to the energy of test pulse 402. A processor and/or controller of the lidar system determines the individual pulse energy amount of test pulse 402 based on the determined numerical value provided by pulse-energy circuit 600. By the relationship between output pulse 401 and test pulse 402, the pulse energy of output pulse 401 is also determined. In various embodiments, the output pulse measurement can be used to modify the operating parameters of light source 110, such as powering up or down light source 110 and/or its components.

FIG. 11 illustrates an example fiber-optic amplifier. In various embodiments, the embodiment of fiber-optic amplifier 500 shown in FIG. 11 can be used as a fiber-optic amplifier in a light source for a lidar system. For example, in some embodiments, fiber-optic amplifier 500 is fiber-optic amplifier 500 of FIG. 10. In the example shown, fiber-optic amplifier 500 includes input and output isolators 530, gain fiber 501, pump laser 510, and pump WDM 520. Fiber-optic amplifier 500 receives light pulse 400a, such as SOA amplified light pulse 400a of FIG. 10, and outputs emitted beam 124, which includes emitted pulse 400. Emitted pulse 400 is generated by amplifying light pulse 400a using fiber-optic amplifier 500 and directed to splitter 470. Splitter 470 splits emitted beam 124 into output beam 125 and test beam 126. Test beam 126 is directed to pulse-energy circuit 600. Similar to the example of FIGS. 9 and 10, in FIG. 11, emitted beam 124, output beam 125, and test beam 126 include corresponding light pulses emitted pulse 400, output pulse 401, and test pulse 402, respectively. In the example shown, the fiber-optic system includes output collimator 570 to direct and/or narrow output beam 125. In various embodiments, the components of FIG. 11 are integrated into a lidar system, such as lidar system 100 of FIGS. 1-4, for performing pulse-energy measurements and output beam 125 is output beam 125 of FIGS. 1-4, 6-8, and/or 10. In some embodiments, splitter 470 is splitter 470 of FIGS. 6-8 and/or 10 and pulse-energy circuit 600 is pulse-energy circuit 600 of FIG. 6 and/or 10. Similarly, emitted beam 124 and emitted pulse 400 are emitted beam 124 and emitted pulse 400 of FIG. 6 and/or 10, output beam 125 and output pulse 401 are output beam 125 and output pulse 401 of FIG. 6 and/or 10, and test beam 126 and test pulse 402 are test beam 126 and test pulse 402 of FIG. 6 and/or 10.

In some embodiments, the energy of one or more instances of test pulse 402 can be determined to be below a particular operating energy. In response to the determination that the energy of the one or more test pulses is below the particular operating energy, an instruction is sent to the light source to increase the energy of the emitted pulses of light. In some embodiments, increasing the energy of the emitted pulses of light comprises increasing an electrical current supplied to pump laser 510 to increase the optical gain of fiber-optic amplifier 500. In some embodiments, pump laser 510 is a pump laser diode.

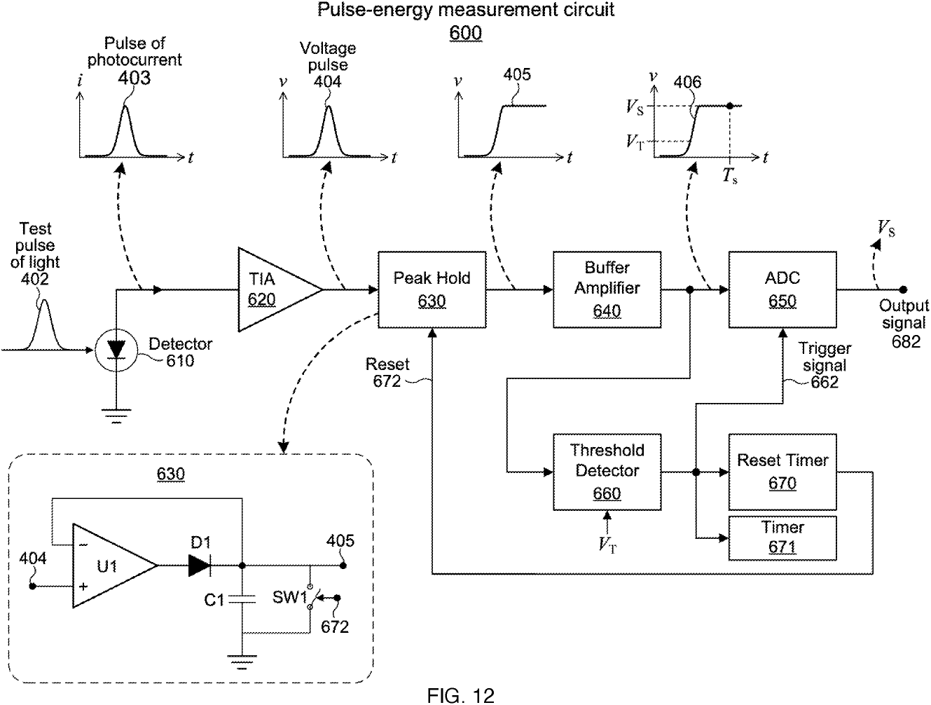

FIG. 12 illustrates an example pulse-energy measurement circuit that includes a peak-hold circuit and an analog-to-digital converter (ADC). In various embodiments, pulse-energy measurement circuit 600 is integrated into a lidar system, such as lidar system 100 of FIGS. 1-4, for performing pulse-energy measurements. For example, using pulse-energy measurement circuit 600, individual light pulses can be measured for their corresponding pulse energy. In some embodiments, a light pulse measured by pulse-energy measurement circuit 600 is a test pulse split from a light pulse generated by a light source such as light source 110 of FIGS. 1, 3, 6, 9, and/or 10. In the example shown, pulse-energy measurement circuit 600 receives test pulse of light 402 and produces output signal 682. In various embodiments, output signal 682 encodes a numerical value that corresponds to the pulse energy of test pulse of light 402. As shown in FIG. 12, pulse-energy measurement circuit 600 includes at least the components detector 610, transimpedance amplifier (TIA) 620, peak-hold circuit 630, buffer amplifier 640, analog-to-digital converter (ADC) 650, threshold detector 660, reset timer 670, and timer 671. An embodiment of peak-hold circuit 630 is shown in detail using a zoomed-in view that includes amplifier U1, diode D1, capacitor C1, and switch SW1. Along the top of FIG. 12, waveforms corresponding to the different signals as they pass through pulse-energy measurement circuit 600 are shown as a function of time t. In some embodiments, pulse-energy measurement circuit 600 is pulse-energy circuit 600 of FIGS. 6, 9, 10, and/or 11, and test pulse of light 402 is test pulse 402 of FIGS. 6, 9, 10, and/or 11.

In the example embodiment of FIG. 12, detector 610 receives test pulse of light 402. Test pulse of light 402 can be a portion of a light beam generated by a light source that is split into test pulse of light 402 and an output pulse. Detector 610 detects test pulse of light 402 and produces a corresponding pulse of photocurrent. Transimpedance amplifier (TIA) 620 receives the pulse of photocurrent and produces a corresponding voltage pulse. Peak hold circuit 630 receives the voltage pulse and produces a voltage signal corresponding to the current detected peak voltage of the received voltage pulse. In various embodiments, peak hold circuit 630 can be implemented using the detailed view shown in the dotted-lined outline. Based on the current detected peak voltage signal, peak hold circuit 630 outputs a peak hold voltage signal to buffer amplifier 640. Buffer amplifier 640 buffers the received voltage signal and outputs a buffered peak hold voltage signal. The buffered peak hold voltage signal corresponds to the current detected voltage peak of test pulse of light 402 and is transmitted to analog-to-digital converter (ADC) 650 and threshold detector 660. For example, buffer amplifier 640 receives the voltage signal from peak hold circuit 630 that corresponds to the peak of the voltage pulse associated with test pulse of light 402 and produces an output voltage signal corresponding to the received voltage signal. ADC 650 converts the received analog signal to produce output signal 682. In various embodiments, output signal 682 is a digital output signal having a numerical value corresponding to the energy of test pulse of light 402 and is determined based on the received buffered voltage signal corresponding to the peak of the voltage pulse. In the example shown, ADC 650 also receives trigger signal 662 as an input signal. Trigger signal 662 is an input trigger to ADC 650 that when activated initiates ADC 650 to produce a valid output signal 682 corresponding to the energy amount of test pulse of light 402. In various embodiments, a processor and/or controller of the lidar system determines the individual pulse energy amount of test pulse of light 402 based on the numerical value corresponding to the energy of test pulse of light 402 provided via output signal 682.

In various embodiments, trigger signal 662 is sent by threshold detector 660 based on the received buffered peak hold voltage signal provided by buffer amplifier 640. In particular embodiments, threshold detector 660 initiates the operation of ADC 650 via trigger signal 662 when the received buffered peak hold voltage signal exceeds or rises above a particular threshold voltage value V_{T}. As shown in the rightmost waveform at the top of FIG. 12, threshold voltage value V_{T} corresponds to the start of a voltage pulse that peaks at Vs. By triggering ADC 650 at the time associated with threshold voltage value V_{T}, ADC 650 is initiated to determine and output a numerical value that corresponds to the energy amount of test pulse of light 402. In some embodiments, the energy amount is based on when test pulse of light 402 reaches its corresponding peak V_{T} at time Ts. For example, in the event a test pulse of light is detected by pulse-energy measurement circuit 600, output signal 682 encodes a numerical value that corresponds to the peak voltage (shown as Vs) of a detected light pulse. In some embodiments, the numerical value is the peak voltage (Vs), the power associated with the test pulse, and/or the energy associated with the test pulse. In some embodiments, Vs corresponds to a buffered peak hold voltage signal associated with the voltage peak of test pulse of light 402. In some embodiments, the numerical value encoded by output signal 682 is based on peak voltage (Vs) and the encoded numerical value is used by the processor and/or controller of the lidar system to determine the individual pulse energy amount of test pulse of light 402.

In addition to transmitting trigger signal 662 to ADC 650, threshold detector 660 also transmits trigger signal 662 to reset timer 670 and timer 671 to initiate their respective functionalities. In some embodiments, reset timer 670 initiates a timer that resets peak-hold circuit 630 when the timer expires. For example, reset timer 670 transmits reset signal 672 to peak-hold circuit 630 to reset the peak voltage being held by peak-hold circuit 630. In various embodiments, reset timer 670 is configured to send reset signal 672 based on the expected timing associated with a light pulse received by pulse-energy measurement circuit 600. For example, reset timer 670 can be configured to supply reset signal 672 to peak-hold circuit 630 at a particular time interval after trigger signal 662 is produced by threshold detector 660. In some embodiments, the timer of reset timer 670 can be configured based on the time associated with the pulse width of test pulse of light 402. In some embodiments, reset timer 670 is implemented by detecting a falling edge or end of a light pulse. For example, threshold detector 660 can detect both a rising edge and a falling edge of a light pulse and send corresponding trigger signals to ADC 650, reset timer 670, and/or timer 671 based on the appropriately detected edge.

In some embodiments, timer 671 receives trigger signal 662 from threshold detector 660 to initiate outputting a time value or timestamp. For example, timer 671 can be configured to determine a time of receipt associated with test pulse of light 402 by outputting the corresponding receipt time when trigger signal 662 is sent by threshold detector 660. In various embodiments, the outputted receipt time corresponds to the numerical value encoded by output signal 682. Although not shown in FIG. 12, timer 671 (and other components of FIG. 12) can include additional connections such as an output signal to transmit the time receipt. In some embodiments, the time receipt is transmitted to a controller unit such as controller 150 of FIG. 1.

As shown along the top of FIG. 12, four waveform graphs depict different signals as they are produced by different components of pulse-energy measurement circuit 600. The waveform graphs show (from left to right) the output result of detector 610 as pulse of photocurrent waveform 403, the output result of TIA 620 as voltage pulse waveform 404, the output result of peak-hold circuit 630 as peak hold voltage signal waveform 405, and the output result of buffer amplifier 640 as buffered peak hold voltage signal waveform 406.

In the lower-left corner of FIG. 12, an embodiment of peak-hold circuit 630 is shown in detail. The detailed embodiment shows that peak-hold circuit 630 receives as an input a voltage pulse (i.e., a voltage pulse corresponding to voltage pulse waveform 404) and produces a voltage signal corresponding to a peak of the received voltage pulse (i.e., peak hold voltage signal waveform 405). Peak-hold circuit 630 also receives as an input reset signal 672 from reset timer 670. When reset signal 672 is received, switch SW1 is closed until the energy held at capacitor C1 is released. By closing switch SW1, the peak hold voltage held by peak-hold circuit 630 is reset.

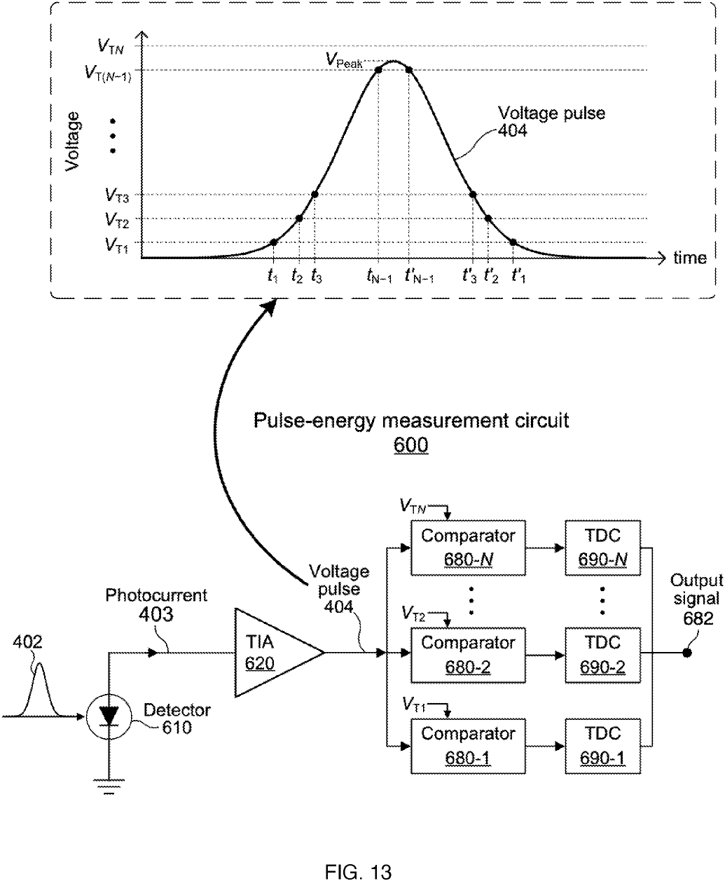

FIG. 13 illustrates an example pulse-energy measurement circuit that includes multiple comparators and time-to-digital converters (TDCs). In some embodiments, pulse-energy measurement circuit 600 is pulse-energy circuit 600 of FIGS. 6, 9, 10, and/or 11 and utilizes components similar to a lidar receiver such as receiver 140 of FIGS. 1 and/or 3 . In the example shown, pulse-energy measurement circuit 600 receives test pulse of light 402 and produces output signal 682. In various embodiments, output signal 682 corresponds to the pulse energy of test pulse of light 402. In various embodiments, voltage pulse 404 and received test pulse of light 402 have similar rise times, fall times, shapes, durations, or other similar pulse characteristics. In particular embodiments, pulse-energy measurement circuit 600 includes detector 610, transimpedance amplifier (TIA) 620, multiple comparators 680, and multiple time-to-digital converters (TDCs) 690. Detector 610 is configured to receive test pulse of light 402 and produce a pulse of photocurrent 403 corresponding to test pulse of light 402. TIA 620 is an electronic amplifier and produces voltage pulse 404 corresponding to the pulse of photocurrent 403 that is sent to multiple comparators 680 and multiple TDCs 690. The produced output signal 682 encodes a numerical value that corresponds to the pulse energy of test pulse of light 402. In various embodiments, the numerical value is determined based on one or more time values produced by one or more of the multiple TDCs 690. In some embodiments, pulse-energy measurement circuit 600 is pulse-energy circuit 600 of FIGS. 6, 9, 10, and/or 11 and test pulse of light 402 is test pulse 402 of FIGS. 6, 9, 10, and/or 11.

In FIG. 13, voltage pulse 404 produced by the TIA 620 is coupled to N comparators (comparators 680-1, 680-2, ..., 680-N), and each comparator is supplied with a particular threshold voltage V_{T1}, V_{T2}, ...,V_{TN}). Pulse-energy measurement circuit 600 may include 1, 2, 5, 10, 50, 100, 500, 1000, or any other suitable number of comparators 680, and each comparator 680 may be supplied with a different threshold voltage. For example, pulse-energy measurement circuit 600 in FIG. 13 may include N = 10 comparators, and the threshold voltages may be set to 10 values between 0 volts and 1 volt (e.g., V_{T1}=0.1 V, V_{T2}=0.2 V, and V_{T10}=1.0 V). Each comparator may produce an electrical-edge signal (e.g., a rising or falling electrical edge) when the voltage pulse 404 rises above or falls below a particular threshold voltage. For example, comparator 680-2 may produce a rising edge (at time t₂) when the voltage pulse 404 rises above the threshold voltage V_{T2}, and comparator 680-2 may produce a falling edge (at time t’₂) when the voltage pulse 404 falls below the threshold voltage V_{T2}.

Pulse-energy measurement circuit 600 in FIG. 13 includes N time-to-digital converters (TDCs 690-1, 690-2, ..., 690-N), and each comparator 680 is coupled to a TDC 690. Each comparator-TDC pair in FIG. 13 (e.g., comparator 680-1 and TDC 690-1) may be referred to as a threshold detector. A comparator may provide an electrical-edge signal to a corresponding TDC, and the TDC may act as a timer that produces an electrical output signal that represents a time when the edge signal is received from the comparator. For example, when voltage pulse 404 rises above the threshold voltage V_{T1} at time t₁, comparator 680-1 may produce a rising-edge signal that is supplied to the input of TDC 690-1, and the TDC 690-1 may produce a digital time value corresponding to time t₁. Additionally, when voltage pulse 404 subsequently falls below the threshold voltage V_{T1}at time t'₁ the comparator 680-1 may produce a falling-edge signal that is supplied to the input of TDC 690-1, and TDC 690-1 may produce another digital time value corresponding to time t'₁.The digital time values may be referenced to a time when test pulse of light 402 is emitted by a light source such as light source 110 of FIGS. 1, 3, 6, 9, and/or 10, and one or more digital time values may correspond to or may be used to at least in part determine the pulse energy corresponding to test pulse of light 402 for a lidar system, such as lidar system 100 of FIGS. 1-4.

In particular embodiments, an output signal 682 of a pulse-energy measurement circuit 600 may include an electrical signal that corresponds to received test pulse of light 402. For example, output signal 682 in FIG. 13 may be a digital signal that corresponds to analog voltage pulse 404, which in turn corresponds to photocurrent 403, which in turn corresponds to received test pulse of light 402. Output signal 682 may further include one or more digital time values from each of the TDCs 690 that received one or more edge signals from a comparator 680, and the digital time values may represent analog voltage pulse 404. For example, TDC 690-1 may provide two digital time values (corresponding to times t₁ and t'₁) as part of output signal 682. Similarly, TDC 690-2 may provide two digital time values (corresponding to times t₂ and t'₂),and TDC 690-3 may provide two digital time values (corresponding to times t₃ and t'3). Output signal 682 from a pulse-energy measurement circuit 600 may be sent to a controller, such as controller 150 of FIG. 1, and a time of arrival for the received test pulse of light 402 (which may be referred to as a time of receipt for the received test pulse of light) may be determined based at least in part on the time values produced by the TDCs. For example, the time of arrival may be determined from a time associated with a peak (e.g., Vₚₑₐₖ), a temporal center (e.g., a centroid or weighted average), or a rising or falling edge of voltage pulse 404.

In some embodiments, output signal 682 in FIG. 13 may include digital values from each of the TDCs that receive an edge signal from a comparator, and each digital value may represent a time interval between the emission of an optical pulse by a light source 110 and the receipt of an edge signal from a comparator. For example, a light source 110 (not shown) may emit a pulse of light that is split into a test pulse and an output pulse. The test pulse can be received by pulse-energy measurement circuit 600 and correspond to input test pulse of light 402. When the light source emits the pulse of light, a count value of the TDCs may be reset to zero counts, and a digital value produced by a TDC 690 may represent an amount of time elapsed since the pulse of light was emitted. Alternatively, the TDCs in pulse-energy measurement circuit 600 may accumulate counts continuously over multiple pulse periods (e.g., for 10, 100, 1,000, 10,000, or 100,000 pulse periods), and when a pulse of light is emitted, instead of resetting a TDC count value to zero counts, a TDC count associated with the time when the pulse was emitted may be stored in memory. After the pulse of light is emitted, the TDCs may continue to accumulate counts that correspond to elapsed time without resetting the TDC count value to zero counts. In this case, a digital value produced by a TDC 690 may represent a count value at the time an edge signal is received by the TDC 690. Additionally, an amount of time elapsed since the pulse of light was emitted may be determined by subtracting a count value associated with the emission of the pulse of light from the count value of the edge signal associated with a received test pulse of light 402.

In some embodiments, when TDC 690-1 receives an edge signal from comparator 680-1, the TDC 690-1 may produce a digital signal that represents the time interval between emission of a test pulse of light 402 and receipt of the edge signal. For example, the digital signal may include a digital value that corresponds to the number of clock cycles that elapsed between emission of the test pulse of light and receipt of the edge signal. Alternatively, if the TDC 690-1 accumulates counts over multiple pulse periods, then the digital signal may include a digital value that corresponds to the TDC count at the time of receipt of the edge signal. Output signal 682 may include digital values corresponding to one or more times when a test pulse of light was emitted and one or more times when a TDC received an edge signal. Output signal 682 from pulse-energy measurement circuit 600 may correspond to a received pulse of light and may include digital values from each of the TDCs that receive an edge signal from a comparator. Output signal 682 may be sent to a controller, such as controller 150 of FIG. 1, and the controller may determine whether the associated lidar system is functioning correctly based at least in part on output signal 682. Additionally or alternatively, the controller may determine an optical characteristic of a test pulse of light 402 based at least in part on output signal 682 received from the TDCs of pulse-energy measurement circuit 600. An optical characteristic of a received pulse of light may include a peak optical intensity, a peak optical power, an average optical power, an optical energy, a shape or amplitude, a time of arrival, a temporal center, a round-trip time of flight, a rise time, a fall time, or a temporal duration or width of the received pulse of light.

In some embodiments, the example voltage pulse 404 illustrated in FIG. 13 corresponds to test pulse of light 402. Voltage pulse 404 may be an analog signal produced by TIA 620 and may correspond to test pulse of light 402 detected by pulse-energy measurement circuit 600. The voltage levels on the y-axis correspond to the threshold voltages V_{T1}, V_{T2}, ..., V_{TN} of the respective comparators 680-1, 680-2, ..., 680-N. The time values t₁, t₂, t₃, ..., t_{N}-₁ correspond to times when voltage pulse 404 exceeds the corresponding threshold voltages, and the time values t'₁,t'₂,t'₃, ..., t'_{N-1}correspond to times when voltage pulse 404 falls below the corresponding threshold voltages. For example, at time t₁ when voltage pulse 404 exceeds the threshold voltage V_{T1}, comparator 680-1 may produce an edge signal, and TDC 690-1 may output a digital value corresponding to the time t₁. Additionally, the TDC 690-1 may output a digital value corresponding to the time t'₁ when voltage pulse 404 falls below the threshold voltage V_{T1}. Alternatively, pulse-energy measurement circuit 600 may include an additional TDC (not illustrated in FIG. 13) configured to produce a digital value corresponding to time t'₁ when voltage pulse 404 falls below the threshold voltage V_{T1}. Output signal 682 from pulse-energy measurement circuit 600 may include one or more digital values that correspond to one or more of the time values t₁, t₂, t₃, ..., t_{N-1}and t'₁, t'₂, t'₃, ..., t'N-1. Additionally, output signal 682 may also include one or more values corresponding to the threshold voltages associated with the time values. Since voltage pulse 404 in FIG. 13 does not exceed the threshold voltage V_{TN}, the corresponding comparator 680-N may not produce an edge signal. As a result, TDC 690-N may not produce a time value, or TDC 690-N may produce a signal indicating that no edge signal was received.

In some embodiments, a time of receipt for a test pulse of light 402 may correspond to (i) a time associated with a peak of voltage pulse 404, (ii) a time associated with a temporal center of voltage pulse 404, or (iii) a time associated with a rising edge of voltage pulse 404. For example, in FIG. 13 a time associated with the peak voltage (Vₚₑₐₖ) may be determined based on the threshold voltage V_{T}(_{N}-₁) (e.g., an average of the times t_{N-1}and t'_{N-1}may correspond to the peak-voltage time). As another example, a curve-fit or interpolation operation may be applied to the values of output signal 682 to determine a time associated with the peak voltage or rising edge. A curve may be fit to the values of output signal 682 to produce a curve that approximates the shape of test pulse of light 402, and a time associated with the peak or rising edge of the curve may correspond to a peak-voltage time or a rising-edge time. As another example, a curve that is fit to the values of output signal 682 of pulse-energy measurement circuit 600 may be used to determine a time associated with a temporal center of voltage pulse 404 (e.g., the temporal center may be determined by calculating a centroid or weighted average of the curve). In various embodiments, a processor and/or controller of the lidar system determines a shape of test pulse of light 402 based on one or more time values produced by one or more of TDCs 690. In the event the determined shape is different from an expected shape, the processor and/or controller can send in response to determining that the shape of test pulse of light 402 is different from the expected shape, an alert that the lidar system is not operating properly

In some embodiments, a duration of test pulse of light 402 is determined. The duration may be determined from a duration or width of corresponding voltage pulse 404. For example, the difference between two time values of output signal 682 may be used to determine a duration of test pulse of light 402. In the example of FIG. 13, the duration of test pulse of light 402 corresponding to voltage pulse 404 may be determined from the difference (t'₃₋ₜ₃), which may correspond to a received pulse of light with a pulse duration of 4 nanoseconds. As another example, a controller may apply a curve-fit or interpolation operation to the values of output signal 682, and the duration of the pulse of light may be determined based on a width of the curve (e.g., a full width at half maximum of the curve). In various embodiments, a processor and/or controller of the lidar system determines a duration of test pulse of light 402 based on one or more time values produced by one or more of TDCs 690. In the event the determined duration is different from an expected duration, the processor and/or controller can send in response to determining that the duration of test pulse of light 402 is different from the expected duration, an alert that the lidar system is not operating properly.

In particular embodiments, a temporal correction or offset may be applied to a determined time of emission to account for signal delay within a lidar system. For example, there may be a time delay of 2 ns between an electrical trigger signal that initiates emission of a pulse of light and a time when the emitted pulse of light exits the lidar system. To account for the 2-ns time delay, a 2-ns offset may be added to an initial time of emission determined by pulse-energy measurement circuit 600 or a controller of the lidar system. For example, pulse-energy measurement circuit 600 may receive an electrical trigger signal at time t_{TRIG} indicating emission of a pulse of light by a corresponding light source. To compensate for the 2-ns delay between the trigger signal and the pulse of light exiting the lidar system, the emission time of the pulse of light may be indicated as (t_{TRIG}+2 ns).

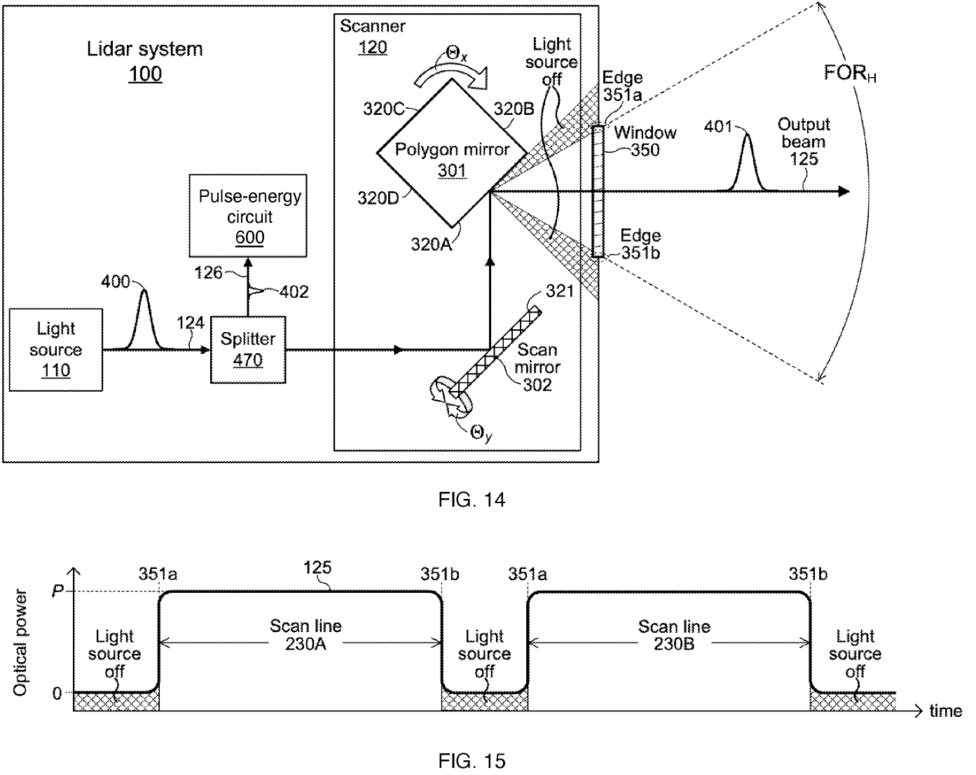

FIG. 14 illustrates an example lidar system that includes an optical splitter and pulse-energy measurement circuit. Similar to lidar system 100 of FIG. 3, lidar system 100 of FIG. 14 includes an example rotating polygon mirror 301. For example, scanner 120 of lidar system 100 includes polygon mirror 301 configured to scan output beam 125 across a suitable field of regard (FOR) having a horizontal FOR (FOR_{H}) for each horizontal scan line. In the example of FIG. 14, scanner 120 includes two scanning mirrors: (1) polygon mirror 301 that rotates along the Oₓ direction and (2) scanning mirror 302 that oscillates back and forth along the O_{y} direction. Light source 110 produces emitted beam 124 which is split by splitter 470 into output beam 125 and test beam 126. Since light source 110 is configured to output light pulses, emitted beam 124 includes emitted pulse 400, output beam 125 includes output pulse 401, and test beam 126 includes test pulse 402. Utilizing scan mirror 302 and polygon mirror 301, output beam 125 is directed out of an opening of the enclosure of lidar system 100 and passes through window 350. In various embodiments, window 350 covers the opening of the enclosure for lidar system 100 and allows output beam 125 to be transmitted towards a target environment while also providing protection to lidar system 100 from environmental elements. The enclosure opening covered by window 350 has defined edges 351a and 351b.

In some embodiments, lidar system 100 of FIG. 14 is lidar system 100 of FIGS. 1-4, light source 110 is light source 110 of FIGS. 1, 3, 6, 9 and/or 10, pulse-energy circuit 600 is pulse-energy circuit 600 of FIGS. 6, 9, 10, and/or 11, and/or pulse-energy measurement circuit 600 of FIGS. 12 and/or 13, splitter 470 is splitter 470 of FIGS. 6-9, 10, and/or 11, output beam 125 is output beam 125 of FIGS. 1-4 and/or 6-11 , and test pulse 402 is test pulse 402 of FIGS. 6 and/or 9-13 . In some embodiments, scanner 120 and its components including polygon mirror 301 and scan mirror 302 are scanner 120 of FIGS. 1 and/or 3 and/or corresponding polygon mirror 301 and scan mirror 302 of FIG. 3, respectively. In various embodiments, lidar system 100 of FIG. 14 scans a target environment as described with respect to FIG. 3. Lidar system 100 includes pulse-energy measurement circuitry including splitter 470 and pulse-energy circuit 600 that are utilized at least in part to measure the pulse energy associated with individual light pulses such as emitted pulse 400, output pulse 401, and/or test pulse 402. By measuring the pulse energy of individual pulses using the disclosed pulse-energy measurement circuitry, lidar system 100 can confirm that light source 110 is operating at the correct power levels including in a powered off and/or appropriately attenuated state at the appropriate times. For example, when polygon mirror 301 directs output beam 125 out of the opening of the enclosure of lidar system 100 (i.e., the opening defined at least in part by edges 351a and 351b) and through window 350, light source 110 can be powered up and transmit corresponding output pulse 401. In contrast, when polygon mirror 301 is not positioned to direct output beam 125 to pass out of the enclosure opening and through window 350, light source 110 can be attenuated and/or turned off. For example, when scanning up to edge 351a and past edge 351b, the areas shown as the hashed triangular areas of FIG. 14, light source 110 can be turned off or lowered in power. In some embodiments, the portions shown by the hashed triangular areas of FIG. 14 correspond to an eclipse period of lidar system 100 when no output beam is directed out of lidar system 100.

In some embodiments, polygon mirror 301 is configured to rotate along a Θₓ direction and scan output beam 125 along a substantially horizontal direction. A rotation along a Oₓ direction may refer to a rotational motion of mirror 301 that results in output beam 125 scanning along a substantially horizontal direction. In FIG. 14, mirror 302 pivots along the O_{y} direction and scans output beam 125 along a substantially vertical direction. In particular embodiments, output beam 125 may be reflected sequentially from reflective surfaces 320A, 320B, 320C, and 320D as polygon mirror 301 is rotated. This results in output beam 125 being scanned along a particular scan axis (e.g., a horizontal scan axis) to produce a sequence of scan lines, where each scan line corresponds to a reflection of output beam 125 from one of the reflective surfaces of polygon mirror 301. In FIG. 14, output beam 125 reflects off of reflective surface 320A to produce one scan line. Then, as the polygon mirror 301 rotates, output beam 125 reflects off of reflective surfaces 320B, 320C, and 320D to produce a second, third, and fourth respective scan line. In particular embodiments, lidar system 100 is configured so output beam 125 is first reflected from scan mirror 302 and then from polygon mirror 301. For example, emitted beam 124 is split by splitter 470 to produce output beam 125. Output beam 125 is first directed to scan mirror 302, where it is reflected by reflective surface 321, and then output beam 125 is directed to polygon mirror 301, where it is reflected by reflective surface 320A.

FIG. 15 illustrates an example graph of the optical power of an output beam plotted versus time. In the example shown, the graph of FIG. 15 displays the optical power of lidar system 100 of FIG. 14 over time as polygon mirror 301 of FIG. 14 is rotated and output beam 125 is scanned along a particular scan axis (e.g., a horizontal scan axis) to produce a sequence of two scan lines corresponding to scan lines 230A and 230B. As shown in FIG. 15, the optical power transitions between values P and 0. When the light source is off, light source 110 of FIG. 14 is powered down or attenuated to reduce the optical power down to 0. These time periods correspond to the periods of time when polygon mirror 301 of FIG. 14 is not positioned to direct output beam 125 between edges 351a and 351b to pass through window 350 towards the target environment. For example, the portion of the graph attributed to scan line 230A corresponds to when output beam 125 reflects off of one of the reflective surfaces 320A, 320B, 320C, or 320D of FIG. 14 to produce a single scan line. As polygon mirror 301 of FIG. 14 continues to pivot, an eclipse period begins once edge 351b is reached. As shown in the graph of FIG. 14, the light source is turned off (and/or attenuated) during the eclipse period. In various embodiments, by powering down the light source during the eclipse period, stray light pulses directed within the enclosure of lidar system 100 are reduced allowing lidar system 100 to operate more efficiency, accurately, and/or to perform additional functionality such as additional test and/or monitoring functionality. As polygon mirror 301 of FIG. 14 continues to pivot, when edge 351a is reached, the eclipse period ends and a second scan line 230B is produced as output beam 125 reflects off of the next reflective surface of polygon mirror 301 FIG. 14. and is directed to pass through window 350 of FIG. 14. In some embodiments, the hashed areas in the graph of FIG. 15 where the light source is off correspond to the hashed triangular areas of FIG. 14 and to eclipse periods created by pivoting polygon mirror 301 of FIG. 14. In various embodiments, the power values shown in the graph of FIG. 15 for portions associated with scan line 230A and 230B are average power values and the power values for each scan line correspond to multiple output pulses.

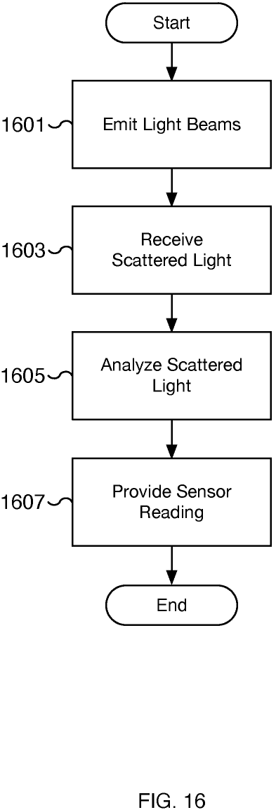

FIG. 16 is a flow chart illustrating an embodiment of a process of a lidar system for detecting objects. Using the process of FIG. 16, a lidar system can detect objects such as objects downrange from the lidar system. For example, a vehicle equipped with the disclosed lidar system can detect other vehicles, pedestrians, lane markers, and street signs, etc. that are downrange from the vehicle. Depending on the orientation and number of lidar systems installed on the vehicle, different fields of regard can be scanned to determine the corresponding environment surrounding the vehicle. Vehicle safety features as well as autonomous driving features can be implemented using the captured environmental data. In various embodiments, the process of FIG. 16 can be performed by the disclosed lidar systems to detect downrange objects by emitting light pulses of one or more wavelengths. When an emitted light pulse hits an object, at least a portion of the scattered and/or reflected light can be captured by the lidar system as part of an input beam. In some embodiments, the lidar system performing the process of FIG. 16 is lidar system 100 of FIGS. 1-4 and/or 14 and the light source of the lidar system is light source 110 of FIGS. 1, 3, 6, 9, 10, and/or 14.

At 1601, one or more light beams are emitted. For example, an output light beam is emitted from the lidar system as light pulses. In some embodiments, the lidar system emits multiple output beams, each potentially offset and/or scanning a different field of regard. In some embodiments, the one or more of the different output beams are at different wavelengths and the different wavelength output beams can be separated in time by an encoding time delay. The encoding time delay used can be stored, for example, as a history of transmitted encoding time delays, and used to match received reflected light to the original transmitted source. In various embodiments, each output beam and corresponding output pulse can reach downrange objects and can be scattered and/or reflected by the downrange object. In some embodiments, each light source used to emit light beams can include a configurable laser capable of emitting light pulses of different wavelengths. In some embodiments, the individual pulse energy of one or more output light pulses is monitored and used to operate the lidar system. For example, based on the measured pulse energy of a light pulse, the power of the light source of the lidar system can be confirmed to be powered up, powered down, and/or properly attenuated. As another example, a fault condition can be identified and raised by comparing the measured pulse energy of a light pulse to its expected pulse energy.

At 1603, scattered light is received. For example, light scattered and/or reflected by an object is received at the lidar sensor. The corresponding object can be a downrange object. In various embodiments, the received light has a particular wavelength and corresponds to one of the light beams and corresponding light pulses emitted at 1601. For example, a lidar system emits light pulses of different wavelengths and receives scattered light associated with the different emitted pulses.

At 1605, the received scattered light is analyzed. For example, the received scattered light is directed to a receiver component of the lidar system where sensor data can be captured and analyzed. In some embodiments, the receiver component includes a receive lens for focusing the received scattered light onto a readout integrated circuit (ROIC) of the receiver where one or more detector site locations of the detector plane are located. The detector site locations can be used to detect scatter patterns associated with the received scattered light and the different detector site locations can be offset at least in part to minimize crosstalk between light corresponding to differently aimed output beams. In some embodiments, the received scattered light includes multiple wavelengths that are then split into their different corresponding received pulses by wavelength.

Using detectors positioned at the detector site locations, sensor data can be captured and analyzed for sensor readings. In some embodiments, the analysis is performed at least in part by the readout integrated circuit (ROIC) and/or processor of the receiver and/or a controller of the lidar system. The processing can include determining an output signal corresponding to the detected scatter pattern. In some embodiments, the output signal is a sensor reading that corresponds to a measurement of the detected scattered light, such as an intensity reading or another measured sensor reading. In some embodiments, the received scattered light is associated into groups of received light pulses and the timing between different light pulses in a group is measured. Based on the measured timing, different light pulses are differentiated from one another and used to identify a corresponding transmit pulse to match a received pulse.

At 1607, a sensor reading is provided. For example, one or more sensor readings are provided in response to the analysis of the received scattered light performed at 1605. The sensor reading can be an intensity reading and/or another measurement or measurements. In some embodiments, the sensor reading includes location and/or distance data. For example, sensor readings can correspond to a point cloud based on objects detected in the fields of regard scanned by the lidar system.

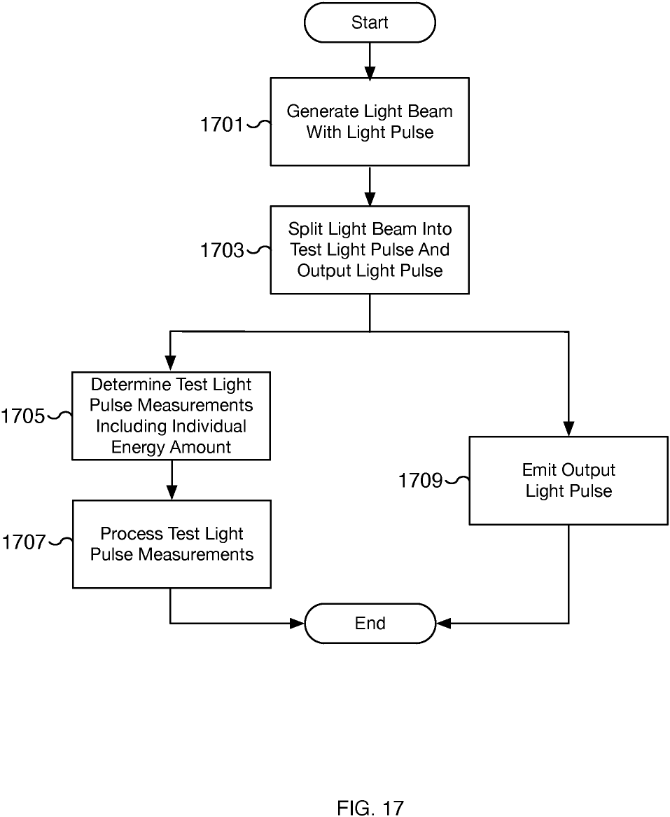

FIG. 17 is a flow chart illustrating an embodiment of a process for monitoring a light pulse of an emitted light beam. Using the process of FIG. 17, a lidar system can monitor light pulses as they are produced by a light source of the lidar system. In various embodiments, the monitored light pulses are measured for individual properties such as peak voltage, power, energy, and/or receipt time. The lidar system can process the monitored measurements to improve performance, efficiency, and/or manage the operation of the lidar system. For example, the monitored measurements can be used to confirm that the light source is properly powered down during eclipse periods and/or that power levels of the emitted light pulses are within an expected operating range. In some embodiments, the monitored measurements are used to detect that the lidar system is operating correctly. In some embodiments, the process of FIG. 17 is performed by a lidar system at 1601 of FIG. 16 as a light pulse of a light beam is emitted. In some embodiments, the lidar system is lidar system 100 of FIGS. 1-4 and/or 14 . In various embodiments, the light source and other relevant components of the lidar system are controlled by a processor and/or controller such as controller 150 of FIG. 1 during the process of FIG. 17.

At 1701, a light beam is generated that includes a light pulse. For example, a light source of the lidar system generates a light beam that includes a light pulse at a particular wavelength. In some embodiments, the light beam is generated by a seed laser and may be amplified by a semiconductor optical amplifier (SOA) and/or a fiber-optic amplifier. In some embodiments, the light beam is generated by light source 110 of FIGS. 1, 3, 6, 9, 10, and/or 14 as emitted beam 124 of FIGS. 6, 7, 8, 9, 10, 11, and/or 14 and the included light pulse is emitted pulse 400 of FIGS. 6, 9, 10, 11, and/or 14.

At 1703, the light beam is split into a test light pulse and an output light pulse. For example, the emitted light beam generated at 1701 includes an emitted light pulse that is split by a splitter into a test light pulse and an output light pulse. The output light pulse can be directed towards a scanner and aimed towards the target environment surrounding the lidar system. The test light pulse can be directed towards a pulse-energy circuit to perform measurements on the test pulse. In some embodiments, the splitter is splitter 470 of FIGS. 6-11 and/or 14, , the pulse-energy circuit is pulse-energy circuit 600 of FIGS. 6, 9-11 and/or 14, and/or pulse-energy measurement circuit 600 of FIGS. 12 and/or 13, and the test pulse of light is test pulse 402 of FIG. 6 and/or 9-14 . In various embodiments, the emitted light pulse is split into a test light pulse and an output light pulse based on a configured split ratio. Using the configured split ratio, for certain measurements such as pulse energy, measurements determined for the test pulse can be used to determine corresponding measurements for the emitted pulse and/or output pulse.

At 1705, test light pulse measurements including an individual energy amount are determined. For example, one or more measurements of the test pulse such as an individual voltage peak measurement of a test pulse can be determined. In some embodiments, the pulse measurements are determined using at least in part a pulse-energy circuit. In some embodiments, the timing of the test pulse is determined and outputted along with other measurements of the test pulse. For example, a numerical value determined based on the peak voltage of the voltage pulse for the test pulse can be outputted along with test pulse timing to determine and track the pulse energy of the test pulse. In some embodiments, additional timing measurements can be determined including the start time of the pulse and the end time of the pulse. In some embodiments, the measurements determined for the test pulse include a duration and/or a shape of the test pulse. In some embodiments, the receipt time determined for the test pulse corresponds to the output of the corresponding output pulse that was split from the emitted pulse at 1703.

At 1707, test light pulse measurements are processed. For example, the measurements determined for the test light pulse at 1705 are processed to manage the operation of the lidar system. In some embodiments, test light pulse measurements are processed using a processor and/or controller of the lidar system. For example, the individual pulse energy amount for a light pulse can be determined by a processor and/or controller based on the test light pulse measurements such as a numerical peak voltage determined at 1705. In some embodiments, the processed results are used to determine whether the lidar system is operating correctly. In the event the system is not operating correctly, an alert that the system is not operating properly can be sent and/or the system can be put into a failover or secondary operating mode. As another example, in some embodiments, the processed pulse measurements are used to determine whether the lidar system is operating within expected operation conditions and/or whether instructions to power up, power down, and/or attenuate the light source were successful. For example, an instruction can be sent to increase the energy of emitted light pulses when one or more test pulses are determined to be below a particular operating energy. By comparing the processed test pulse measurements to expected values, a determination can be made whether the instruction was successfully sent and executed and that the emitted pulses are adjusted consistent with the instruction. As another example, the energy of one or more test pulses of light can be determined to be below a particular minimum energy or outside an operating energy range. In response to either determination, an alert that the lidar system is not operating properly can be sent. In some embodiments, the alert includes an instruction to shut down the lidar system or at least a portion of the lidar system.

In some embodiments, the determined pulse energy of an output pulse is used at least in part to determine the reflectivity of a target. For example, a receiver of the lidar system determines the energy of a received pulse of light comprising a portion of an output pulse of light scattered by a target located at a distance from the lidar system. The lidar system can determine the reflectivity of the target based on the energy of the received pulse of light, the energy of the output pulse of light, and the distance from the lidar system to the target.

At 1709, an output light pulse is emitted from the lidar system. For example, an output pulse is emitted towards a target environment as part of a scanning process to detect objects in the surrounding environment. In various embodiments, the output light pulse is emitted while the test pulse is being measured at 1705 and/or while the test pulse measurements are being processed at 1707. In various embodiments, although the measurements determined at 1705 and processed at 1707 are based on the test pulse, due to the relationship between the emitted pulse, test pulse, and output pulse, the results relate to all three pulses including the output pulse emitted at 1709.

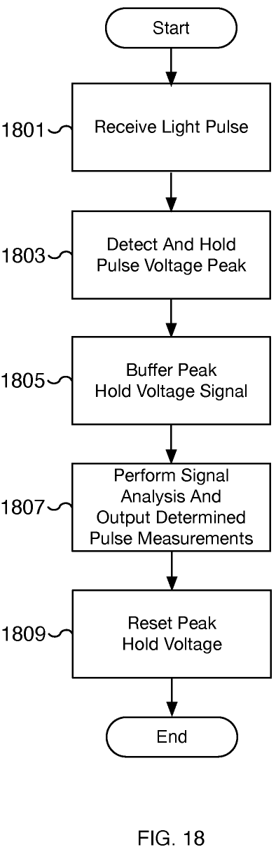

FIG. 18 is a flow chart illustrating an embodiment of a process for determining measurements for a light pulse. Using the process of FIG. 18, a light pulse such as a test pulse can be monitored and analyzed to determine measurements related to the pulse, such as peak voltage and receipt time. In some embodiments, the process is performed at least in part by a pulse-energy circuit of the lidar system. In some embodiments, the pulse-energy circuit is pulse-energy circuit 600 of FIGS. 6, 9-11 and/or 14, and/or pulse-energy measurement circuit 600 of FIGS. 12 and/or 13 . In some embodiments, the light pulse that is measured is test pulse 402 of FIGS. 6 and/or 9-14 . In some embodiments, the process of FIG. 18 is performed at 1705 and/or 1707 of FIG. 17.

At 1801, a light pulse is received. For example, a light pulse such as a test pulse split from an original emitted pulse is received. In some embodiments, the light pulse can be received and detected by a detector such as a photodetector. In some embodiments, the light pulse is received, and a corresponding photocurrent pulse is produced and converted into a voltage pulse. The voltage pulse can be used as an input voltage signal to step 1803.

At 1803, the voltage peak of the light pulse is detected and held. For example, the peak voltage associated with the light pulse received at 1801 is determined and outputted as a voltage signal such as a peak hold voltage signal. In some embodiments, the peak is detected by a peak-hold circuit, such as peak-hold circuit 630 of FIG. 12 and/or peak-hold components of FIG. 13. In some embodiments, the voltage peak is determined based on a voltage signal corresponding to a voltage pulse of the received test pulse.

At 1805, the peak hold voltage signal is buffered. In some embodiments, the peak hold voltage signal generated at 1803 is passed through a buffer amplifier. For example, the peak hold voltage may be passed through a buffer amplifier to prepare the voltage signal for signal processing. In some embodiments, the voltage signal corresponding to the peak hold voltage of the test pulse is buffered to prevent the signal analysis and subsequent processing that is performed from interfering with other functions of the pulse-energy circuit.

At 1807, signal analysis is performed and determined pulse measurements are outputted. For example, signal analysis is performed on the buffered peak hold voltage signal to determine the corresponding peak voltage of the test pulse as a numerical value. In some embodiments, the signal analysis is performed by an analog-to-digital converter (ADC), one or more comparators, and/or one or more time-to-digital converters (TDCs). For example, an ADC can be used at least in part to determine and encode a numerical value corresponding to the peak voltage of the test pulse based on the buffered peak hold voltage signal. In some embodiments, the analysis is performed based on a trigger signal, such as a trigger signal initiated by the rising edge of the test pulse and/or its corresponding voltage signal. In various embodiments, additional measurements can be determined including timing measurements such as the receipt time of the test pulse, the shape of the test pulse, the duration of the test pulse, the time of the rising edge of the test pulse, and/or the time of the falling edge of the test pulse, among others. In various embodiments, a processor and/or controller of the lidar system can determine the individual pulse energy amount of a light pulse based on the determined numerical pulse measurements. By the relationship between an output pulse and a measured corresponding test pulse, the pulse energy of an output pulse can also be determined.

At 1809, the peak hold voltage is reset. For example, once the test pulse is analyzed at 1807 and associated measurements are determined for the test pulse, the peak voltage that was detected for the test pulse and held at 1803 can be reset. In various embodiments, the peak hold voltage is reset in anticipation for measuring the peak voltage of the next test pulse. In some embodiments, the peak hold voltage is reset by sending a reset signal to the peak-hold circuit. In some embodiments, the reset signal is triggered based on a reset timer. For example, a reset timer is configured to send a reset signal when a configured timer expires. In some embodiments, the timer is configured for the amount of time needed to analyze the test pulse and can be based on when the peak hold voltage signal of the test pulse is no longer needed.

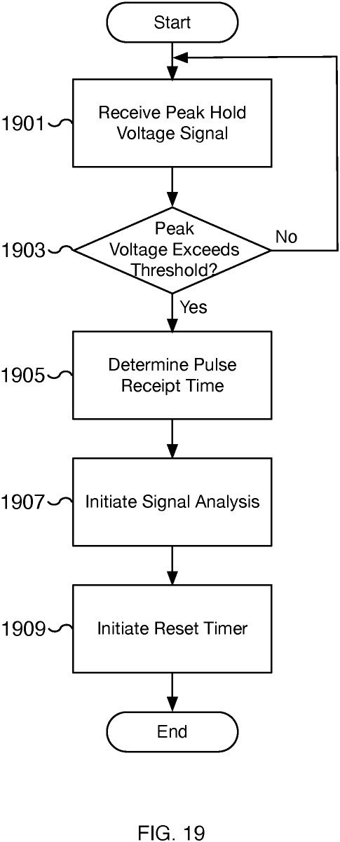

FIG. 19 is a flow chart illustrating an embodiment of a process for initiating signal analysis on a light pulse. Using the process of FIG. 19, signal analysis on a monitored light pulse is initiated based on detecting that a light pulse exceeds a configured threshold voltage. In various embodiments, the process of FIG. 19 is used to initiate evaluation of a test pulse to determine the individual pulse energy of the detected light pulse based on its peak voltage. In some embodiments, the process of FIG. 19 is performed at 1807 of FIG. 18 at least in part by a threshold detector of a pulse-energy measurement circuit such as threshold detector 660 of pulse-energy measurement circuit 600 of FIG. 12. In some embodiments, the process of FIG. 19 further utilizes and relies on additional components of the pulse-energy measurement circuit such as a peak-hold circuit, a buffer amplifier, an analog-to-digital converter (ADC), a reset timer, and a timer. For example, the process of FIG. 19 can utilize peak-hold circuit 630, buffer amplifier 640, analog-to-digital converter (ADC) 650, threshold detector 660, reset timer 670, and timer 671 of FIG. 12.

At 1901, a peak hold voltage signal corresponding to a detected light pulse is received. For example, a light pulse is detected and, at 1901, a voltage signal corresponding to the peak of the voltage pulse of the light pulse is received at a threshold detector. The threshold detector is configured with a voltage threshold value (V_{T}) that is used to trigger signal analysis of the light pulse at the appropriate time. In some embodiments, the peak hold voltage signal is a buffered peak hold voltage signal that is passed through a buffer amplifier. In some embodiments, the peak hold voltage signal is generated at least in part by a peak-hold circuit.

At 1903, a determination is made whether the peak voltage value exceeds the voltage threshold value (V_{T}). In the event the peak voltage value exceeds the voltage threshold value (V_{T}), processing proceeds to 1905. For example, processing proceeds to 1905 when the voltage value of the peak hold voltage signal received at 1901 exceeds the configured voltage threshold value (V_{T}). In various embodiments, the start of a light pulse and its rising edge corresponds to the peak voltage value exceeding the voltage threshold value (V_{T}). In the event the peak voltage value does not exceed the voltage threshold value (V_{T}), processing proceeds back to 1901.

At 1905, the receipt time of the light pulse is determined. For example, the receipt time of the light pulse is determined based on detecting that the peak voltage value exceeds the voltage threshold value (V_{T}) at 1903. In some embodiments, the receipt time is determined by sending a trigger signal to a timer. In some embodiments, the trigger signal is trigger signal 662 of FIG. 12 and the timer is timer 671 of FIG. 12. When the timer receives the trigger signal, the timer marks the current time and associates it with the current light pulse. In some embodiments, the current time is offset by an offset amount to more accurately identify the desired receipt time of the light pulse. For example, the receipt time may correspond to a peak, a rising edge, a temporal center, and/or a failing edge. In some embodiments, multiple receipt times are determined and provided as part of an output signal. In some embodiments, the time of receipt for a light pulse can be used to determine whether the light pulse is outside a time-of-receipt interval. A light pulse with a time of receipt that is outside of a time-of-receipt interval can result in sending an alert that the lidar system is not operating properly.

At 1907, signal analysis of the light pulse is initiated. For example, an analog-to-digital converter (ADC), controller, and/or processor is sent a trigger signal to initiate the analysis of the light pulse. In some embodiments, the trigger signal is trigger signal 662 of FIG. 12 and is sent to initiate processing by analog-to-digital converter (ADC) 650 of FIG. 12 on input parameters based on the detected light pulse. For example, when an ADC receives the trigger signal to initiate processing, the ADC analyzes and converts its received analog input(s) into one or more digital output signals. In various embodiments, an input to the ADC is a peak hold voltage signal corresponding to the peak voltage of the detected light pulse. In some embodiments, the signal analysis triggered by the ADC can include determining a numerical value corresponding to the energy of the light pulse based on a provided peak hold voltage signal of the light pulse. In some embodiments, the peak hold voltage signal is a buffered peak hold voltage signal that is passed through a buffer amplifier. In some embodiments, the output by the ADC of a numerical value corresponding to the energy of the light pulse initiates a processor and/or controller of the lidar system to determine the individual pulse energy amount for the light pulse based at least in part on the provided numerical value.

At 1909, a reset timer is initiated. For example, the reset timer is sent a trigger signal to initiate the start of the reset timer. In various embodiments, the reset timer is configured with a timer that when the time period of the timer expires, a reset signal is sent to reset the peak hold voltage signal. In some embodiments, the reset timer is reset timer 670 of FIG. 12 and the reset timer is initiated via trigger signal 662 of FIG. 12.

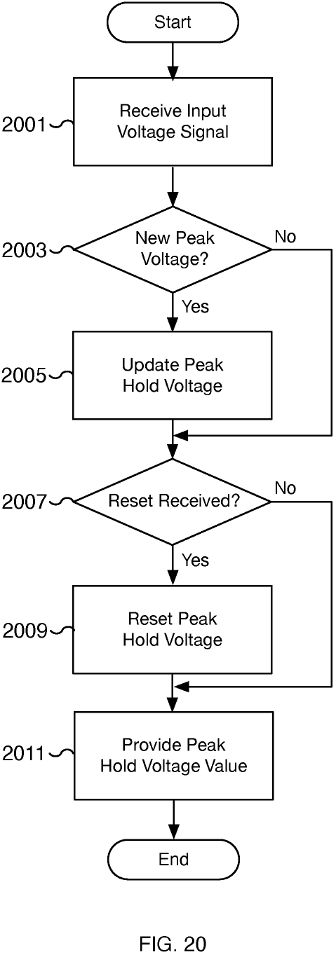

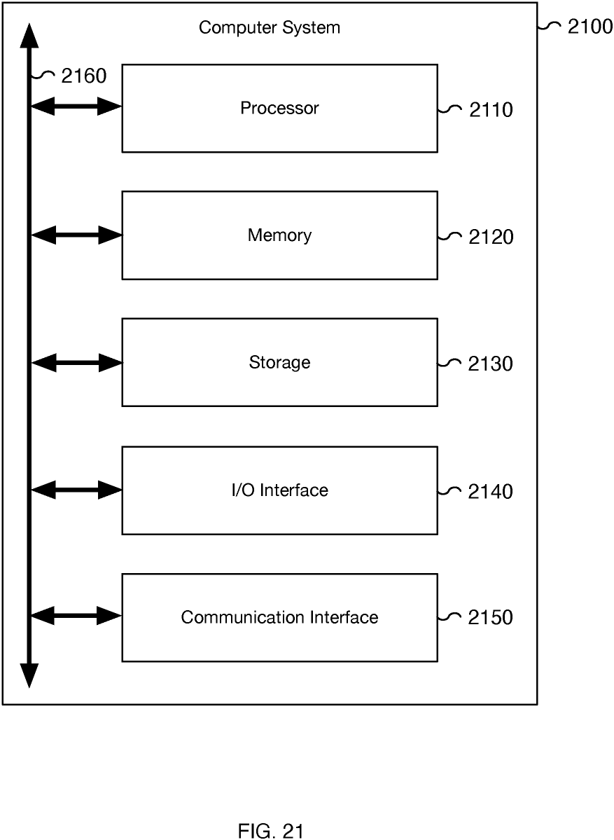

FIG. 20 is a flow chart illustrating an embodiment of a process for outputting a peak hold voltage signal for measuring a light pulse. Using the process of FIG. 20, a peak voltage value of a voltage signal corresponding to a light pulse is outputted as a peak hold voltage signal. In various embodiments, the process of FIG. 20 is performed by a peak-hold circuit such as peak-hold circuit 630 of FIG. 12. In some embodiments, the produced peak hold voltage signal outputted by the process of FIG. 20 is used to detect a light pulse and to determine a pulse energy of the detected light pulse. In various embodiments, the peak hold voltage is initialized to an initial value such as a reset value.

At 2001, an input voltage signal is received. For example, a voltage signal corresponding to a voltage pulse for a light pulse is received. In some embodiments, the voltage signal for the voltage pulse is produced from a photocurrent pulse of the light pulse by using a transimpedance amplifier (TIA) such as transimpedance amplifier (TIA) 620 of FIG. 12.

At 2003, a determination is made whether a new peak voltage is detected. In the event a new peak voltage is detected, processing proceeds to 2005 to update the peak hold voltage. In the event a new peak voltage is not detected, processing proceeds to 2007 and the existing peak voltage is held without change.

At 2005, the peak hold voltage is updated. For example, the peak voltage being held and associated with a light pulse is updated using the newly detected peak voltage. In various embodiments, the peak voltage is held at least in part by a capacitor such as capacitor C1 of peak-hold circuit 630 of FIG. 12.

At 2007, a determination is made whether a reset is received. In the event a reset is received, processing proceeds to 2009. In the event a reset is not received, for example, no reset signal is activated, processing proceeds to 2011.

At 2009, the peak hold voltage is reset. Triggered by the reset detected at 2007, the peak hold voltage is reset. In various embodiments, the peak hold voltage is reset to a reset value to prepare the peak-hold circuit for detecting the peak voltage for the next light pulse. In some embodiments, the peak-hold circuit is reset by releasing the energy held by a capacitor of the peak-hold circuit.

At 2011, the peak hold voltage value is provided. For example, a peak hold voltage signal is outputted by the peak-hold circuit. The peak hold voltage signal provides the current peak hold voltage for the light pulse. In some embodiments, the peak hold voltage signal is provided to a threshold detector to detect the rising edge of the light pulse and to determine its individual pulse energy.

FIG. 21 illustrates an example computer system 2100. In particular embodiments, one or more computer systems 2100 may perform one or more steps of one or more methods described or illustrated herein. In particular embodiments, one or more computer systems 2100 may provide functionality described or illustrated herein. In particular embodiments, software running on one or more computer systems 2100 may perform one or more steps of one or more methods described or illustrated herein or may provide functionality described or illustrated herein. Particular embodiments may include one or more portions of one or more computer systems 2100. In particular embodiments, a computer system may be referred to as a processor, a controller, a computing device, a computing system, a computer, a general-purpose computer, or a data-processing apparatus. Herein, reference to a computer system may encompass one or more computer systems, where appropriate. In some embodiments, computer system 2100 is used to perform one or more of the processes of FIGS. 16-20.

Computer system 2100 may take any suitable physical form. As an example, computer system 2100 may be an embedded computer system, a system-on-chip (SOC), a single-board computer system (SBC), a desktop computer system, a laptop or notebook computer system, a mainframe, a mesh of computer systems, a server, a tablet computer system, or any suitable combination of two or more of these. As another example, all or part of computer system 2100 may be combined with, coupled to, or integrated into a variety of devices, including, but not limited to, a camera, camcorder, personal digital assistant (PDA), mobile telephone, smartphone, electronic reading device (e.g., an e-reader), game console, smart watch, clock, calculator, television monitor, flat-panel display, computer monitor, vehicle display (e.g., odometer display or dashboard display), vehicle navigation system, lidar system, ADAS, autonomous vehicle, autonomous-vehicle driving system, cockpit control, camera view display (e.g., display of a rear-view camera in a vehicle), eyewear, or head-mounted display. Where appropriate, computer system 2100 may include one or more computer systems 2100; be unitary or distributed; span multiple locations; span multiple machines; span multiple data centers; or reside in a cloud, which may include one or more cloud components in one or more networks. Where appropriate, one or more computer systems 2100 may perform without substantial spatial or temporal limitation one or more steps of one or more methods described or illustrated herein. As an example, one or more computer systems 2100 may perform in real time or in batch mode one or more steps of one or more methods described or illustrated herein. One or more computer systems 2100 may perform at different times or at different locations one or more steps of one or more methods described or illustrated herein, where appropriate.

As illustrated in the example of FIG. 21, computer system 2100 may include a processor 2110, memory 2120, storage 2130, an input/output (I/O) interface 2140, a communication interface 2150, or a bus 2160. Computer system 2100 may include any suitable number of any suitable components in any suitable arrangement.

In particular embodiments, processor 2110 may include hardware for executing instructions, such as those making up a computer program. As an example, to execute instructions, processor 2110 may retrieve (or fetch) the instructions from an internal register, an internal cache, memory 2120, or storage 2130; decode and execute them; and then write one or more results to an internal register, an internal cache, memory 2120, or storage 2130. In particular embodiments, processor 2110 may include one or more internal caches for data, instructions, or addresses. Processor 2110 may include any suitable number of any suitable internal caches, where appropriate. As an example, processor 2110 may include one or more instruction caches, one or more data caches, or one or more translation lookaside buffers (TLBs). Instructions in the instruction caches may be copies of instructions in memory 2120 or storage 2130, and the instruction caches may speed up retrieval of those instructions by processor 2110. Data in the data caches may be copies of data in memory 2120 or storage 2130 for instructions executing at processor 2110 to operate on; the results of previous instructions executed at processor 2110 for access by subsequent instructions executing at processor 2110 or for writing to memory 2120 or storage 2130; or other suitable data. The data caches may speed up read or write operations by processor 2110. The TLBs may speed up virtual-address translation for processor 2110. In particular embodiments, processor 2110 may include one or more internal registers for data, instructions, or addresses. Processor 2110 may include any suitable number of any suitable internal registers, where appropriate. Where appropriate, processor 2110 may include one or more arithmetic logic units (ALUs); may be a multi-core processor; or may include one or more processors 2110.

In particular embodiments, memory 2120 may include main memory for storing instructions for processor 2110 to execute or data for processor 2110 to operate on. As an example, computer system 2100 may load instructions from storage 2130 or another source (such as, for example, another computer system 2100) to memory 2120. Processor 2110 may then load the instructions from memory 2120 to an internal register or internal cache. To execute the instructions, processor 2110 may retrieve the instructions from the internal register or internal cache and decode them. During or after execution of the instructions, processor 2110 may write one or more results (which may be intermediate or final results) to the internal register or internal cache. Processor 2110 may then write one or more of those results to memory 2120. One or more memory buses (which may each include an address bus and a data bus) may couple processor 2110 to memory 2120. Bus 2160 may include one or more memory buses. In particular embodiments, one or more memory management units (MMUs) may reside between processor 2110 and memory 2120 and facilitate accesses to memory 2120 requested by processor 2110. In particular embodiments, memory 2120 may include random access memory (RAM). This RAM may be volatile memory, where appropriate. Where appropriate, this RAM may be dynamic RAM (DRAM) or static RAM (SRAM). Memory 2120 may include one or more memories 2120, where appropriate.

In particular embodiments, storage 2130 may include mass storage for data or instructions. As an example, storage 2130 may include a hard disk drive (HDD), a floppy disk drive, flash memory, an optical disc, a magneto-optical disc, magnetic tape, or a Universal Serial Bus (USB) drive or a combination of two or more of these. Storage 2130 may include removable or non-removable (or fixed) media, where appropriate. Storage 2130 may be internal or external to computer system 2100, where appropriate. In particular embodiments, storage 2130 may be non-volatile, solid-state memory. In particular embodiments, storage 2130 may include read-only memory (ROM). Where appropriate, this ROM may be mask ROM (MROM), programmable ROM (PROM), erasable PROM (EPROM), electrically erasable PROM (EEPROM), flash memory, or a combination of two or more of these. Storage 2130 may include one or more storage control units facilitating communication between processor 2110 and storage 2130, where appropriate. Where appropriate, storage 2130 may include one or more storages 2130.

In particular embodiments, I/O interface 2140 may include hardware, software, or both, providing one or more interfaces for communication between computer system 2100 and one or more I/O devices. Computer system 2100 may include one or more of these I/O devices, where appropriate. One or more of these I/O devices may enable communication between a person and computer system 2100. As an example, an I/O device may include a keyboard, keypad, microphone, monitor, mouse, printer, scanner, speaker, camera, stylus, tablet, touch screen, trackball, another suitable I/O device, or any suitable combination of two or more of these. An I/O device may include one or more sensors. Where appropriate, I/O interface 2140 may include one or more device or software drivers enabling processor 2110 to drive one or more of these I/O devices. I/O interface 2140 may include one or more I/O interfaces 2140, where appropriate.

In particular embodiments, communication interface 2150 may include hardware, software, or both providing one or more interfaces for communication (such as, for example, packet-based communication) between computer system 2100 and one or more other computer systems 2100 or one or more networks. As an example, communication interface 2150 may include a network interface controller (NIC) or network adapter for communicating with an Ethernet or other wire-based network or a wireless NIC (WNIC); a wireless adapter for communicating with a wireless network, such as a WI-FI network; or an optical transmitter (e.g., a laser or a light-emitting diode) or an optical receiver (e.g., a photodetector) for communicating using fiber-optic communication or free-space optical communication. Computer system 2100 may communicate with an ad hoc network, a personal area network (PAN), an in-vehicle network (IVN), a local area network (LAN), a wide area network (WAN), a metropolitan area network (MAN), or one or more portions of the Internet or a combination of two or more of these. One or more portions of one or more of these networks may be wired or wireless. As an example, computer system 2100 may communicate with a wireless PAN (WPAN) (such as, for example, a BLUETOOTH WPAN), a WI-FI network, a Worldwide Interoperability for Microwave Access (WiMAX) network, a cellular telephone network (such as, for example, a Global System for Mobile Communications (GSM) network), or other suitable wireless network or a combination of two or more of these. As another example, computer system 2100 may communicate using fiber-optic communication based on 100 Gigabit Ethernet (100 GbE), 10 Gigabit Ethernet (10 GbE), or Synchronous Optical Networking (SONET). Computer system 2100 may include any suitable communication interface 2150 for any of these networks, where appropriate. Communication interface 2150 may include one or more communication interfaces 2150, where appropriate.

In particular embodiments, bus 2160 may include hardware, software, or both coupling components of computer system 2100 to each other. As an example, bus 2160 may include an Accelerated Graphics Port (AGP) or other graphics bus, a controller area network (CAN) bus, an Enhanced Industry Standard Architecture (EISA) bus, a front-side bus (FSB), a HYPERTRANSPORT (HT) interconnect, an Industry Standard Architecture (ISA) bus, an INFINIBAND interconnect, a low-pin-count (LPC) bus, a memory bus, a Micro Channel Architecture (MCA) bus, a Peripheral Component Interconnect (PCI) bus, a PCI-Express (PCIe) bus, a serial advanced technology attachment (SATA) bus, a Video Electronics Standards Association local bus (VLB), or another suitable bus or a combination of two or more of these. Bus 2160 may include one or more buses 2160, where appropriate.

In particular embodiments, various modules, circuits, systems, methods, or algorithm steps described in connection with the implementations disclosed herein may be implemented as electronic hardware, computer software, or any suitable combination of hardware and software. In particular embodiments, computer software (which may be referred to as software, computer-executable code, computer code, a computer program, computer instructions, or instructions) may be used to perform various functions described or illustrated herein, and computer software may be configured to be executed by or to control the operation of computer system 2100. As an example, computer software may include instructions configured to be executed by processor 2110. In particular embodiments, owing to the interchangeability of hardware and software, the various illustrative logical blocks, modules, circuits, or algorithm steps have been described generally in terms of functionality. Whether such functionality is implemented in hardware, software, or a combination of hardware and software may depend upon the particular application or design constraints imposed on the overall system.

In particular embodiments, a computing device may be used to implement various modules, circuits, systems, methods, or algorithm steps disclosed herein. As an example, all or part of a module, circuit, system, method, or algorithm disclosed herein may be implemented or performed by a general-purpose single- or multi-chip processor, a digital signal processor (DSP), an ASIC, a FPGA, any other suitable programmable-logic device, discrete gate or transistor logic, discrete hardware components, or any suitable combination thereof. A general-purpose processor may be a microprocessor, or, any conventional processor, controller, microcontroller, or state machine. A processor may also be implemented as a combination of computing devices, e.g., a combination of a DSP and a microprocessor, a plurality of microprocessors, one or more microprocessors in conjunction with a DSP core, or any other such configuration.

In particular embodiments, one or more implementations of the subject matter described herein may be implemented as one or more computer programs (e.g., one or more modules of computer-program instructions encoded or stored on a computer-readable non-transitory storage medium). As an example, the steps of a method or algorithm disclosed herein may be implemented in a processor-executable software module which may reside on a computer-readable non-transitory storage medium. In particular embodiments, a computer-readable non-transitory storage medium may include any suitable storage medium that may be used to store or transfer computer software and that may be accessed by a computer system. Herein, a computer-readable non-transitory storage medium or media may include one or more semiconductor-based or other integrated circuits (ICs) (such, as for example, field-programmable gate arrays (FPGAs) or application-specific ICs (ASICs)), hard disk drives (HDDs), hybrid hard drives (HHDs), optical discs (e.g., compact discs (CDs), CD-ROM, digital versatile discs (DVDs), blu-ray discs, or laser discs), optical disc drives (ODDs), magneto-optical discs, magneto-optical drives, floppy diskettes, floppy disk drives (FDDs), magnetic tapes, flash memories, solid-state drives (SSDs), RAM, RAM-drives, ROM, SECURE DIGITAL cards or drives, any other suitable computer-readable non-transitory storage media, or any suitable combination of two or more of these, where appropriate. A computer-readable non-transitory storage medium may be volatile, non-volatile, or a combination of volatile and non-volatile, where appropriate.

In particular embodiments, certain features described herein in the context of separate implementations may also be combined and implemented in a single implementation. Conversely, various features that are described in the context of a single implementation may also be implemented in multiple implementations separately or in any suitable sub-combination. Moreover, although features may be described above as acting in certain combinations and even initially claimed as such, one or more features from a claimed combination may in some cases be excised from the combination, and the claimed combination may be directed to a sub-combination or variations of a sub-combination.

While operations may be depicted in the drawings as occurring in a particular order, this should not be understood as requiring that such operations be performed in the particular order shown or in sequential order, or that all operations be performed. Further, the drawings may schematically depict one more example processes or methods in the form of a flow diagram or a sequence diagram. However, other operations that are not depicted may be incorporated in the example processes or methods that are schematically illustrated. For example, one or more additional operations may be performed before, after, simultaneously with, or between any of the illustrated operations. Moreover, one or more operations depicted in a diagram may be repeated, where appropriate. Additionally, operations depicted in a diagram may be performed in any suitable order. Furthermore, although particular components, devices, or systems are described herein as carrying out particular operations, any suitable combination of any suitable components, devices, or systems may be used to carry out any suitable operation or combination of operations. In certain circumstances, multitasking or parallel processing operations may be performed. Moreover, the separation of various system components in the implementations described herein should not be understood as requiring such separation in all implementations, and it should be understood that the described program components and systems may be integrated together in a single software product or packaged into multiple software products.

Various embodiments have been described in connection with the accompanying drawings. However, it should be understood that the figures may not necessarily be drawn to scale. As an example, distances or angles depicted in the figures are illustrative and may not necessarily bear an exact relationship to actual dimensions or layouts of the devices illustrated.

The scope of this disclosure encompasses all changes, substitutions, variations, alterations, and modifications to the example embodiments described or illustrated herein that a person having ordinary skill in the art would comprehend. The scope of this disclosure is not limited to the example embodiments described or illustrated herein. Moreover, although this disclosure describes or illustrates respective embodiments herein as including particular components, elements, functions, operations, or steps, any of these embodiments may include any combination or permutation of any of the components, elements, functions, operations, or steps described or illustrated anywhere herein that a person having ordinary skill in the art would comprehend.

The term “or” as used herein is to be interpreted as an inclusive or meaning any one or any combination, unless expressly indicated otherwise or indicated otherwise by context. Therefore, herein, the expression “A or B” means “A, B, or both A and B.” As another example, herein, “A, B or C” means at least one of the following: A; B; C; A and B; A and C; B and C; A, B and C. An exception to this definition will occur if a combination of elements, devices, steps, or operations is in some way inherently mutually exclusive.

As used herein, words of approximation such as, without limitation, "approximately, "substantially," or "about" refer to a condition that when so modified is understood to not necessarily be absolute or perfect but would be considered close enough to those of ordinary skill in the art to warrant designating the condition as being present. The extent to which the description may vary will depend on how great a change can be instituted and still have one of ordinary skill in the art recognize the modified feature as having the required characteristics or capabilities of the unmodified feature. In general, but subject to the preceding discussion, a numerical value herein that is modified by a word of approximation such as “approximately” may vary from the stated value by ±0.5%, ±1%, ±2%, ±3%, ±4%, ±5%, ±10%, ±12%, or ±15%. The term “substantially constant” refers to a value that varies by less than a particular amount over any suitable time interval. For example, a value that is substantially constant may vary by less than or equal to 20%, 10%, 1%, 0.5%, or 0.1% over a time interval of approximately 10⁴ s, 10³ s, 10² s, 10 s, 1 s, 100 ms, 10 ms, 1 ms, 100 µs, 10 µs, or 1 µs. The term “substantially constant” may be applied to any suitable value, such as for example, an optical power, a pulse repetition frequency, an electrical current, a wavelength, an optical or electrical frequency, or an optical or electrical phase.

As used herein, the terms “first,” “second,” “third,” etc. may be used as labels for nouns that they precede, and these terms may not necessarily imply a particular ordering (e.g., a particular spatial, temporal, or logical ordering). As an example, a system may be described as determining a “first result” and a “second result,” and the terms “first” and “second” may not necessarily imply that the first result is determined before the second result.

As used herein, the terms “based on” and “based at least in part on” may be used to describe or present one or more factors that affect a determination, and these terms may not exclude additional factors that may affect a determination. A determination may be based solely on those factors which are presented or may be based at least in part on those factors. The phrase “determine A based on B” indicates that B is a factor that affects the determination of A. In some instances, other factors may also contribute to the determination of A. In other instances, A may be determined based solely on B.

Although the foregoing embodiments have been described in some detail for purposes of clarity of understanding, the invention is not limited to the details provided. There are many alternative ways of implementing the invention. The disclosed embodiments are illustrative and not restrictive.

What is claimed is:

1. A system, comprising:
a light source configured to generate an emitted beam of light comprising an emitted pulse of light;
an optical splitter configured to split the emitted beam of light to produce at least (i) a test beam of light comprising a test pulse of light, the test pulse of light comprising a first portion of the emitted pulse of light and (ii) an output beam of light comprising an output pulse of light, the output pulse of light comprising a second portion of the emitted pulse of light allowed to at least in part exit the system; and
a pulse-energy measurement circuit configured to receive the test pulse of light and determine a numerical value corresponding to an individual energy amount of the test pulse of light.

2. The system of claim 1, wherein the pulse-energy measurement circuit comprises:
a detector configured to produce a pulse of photocurrent corresponding to the test pulse of light;
an electronic amplifier configured to produce a voltage pulse corresponding to the pulse of photocurrent;
a peak-hold circuit configured to produce a voltage signal corresponding to a peak of the voltage pulse; and
an analog-to-digital converter (ADC) configured to determine the numerical value corresponding to the individual energy amount of the test pulse of light, wherein the numerical value is determined based on the voltage signal corresponding to the peak of the voltage pulse.

3. The system of claim 2, wherein the pulse-energy measurement circuit further comprises a threshold detector configured to produce a trigger signal when the voltage signal rises above a particular threshold voltage, wherein the trigger signal is supplied to the ADC to initiate determination by the ADC of the numerical value corresponding to the individual energy amount of the test pulse of light.

4. The system of claim 3, wherein the pulse-energy measurement circuit further comprises a reset timer configured to supply a reset signal to the peak-hold circuit a particular time interval after the trigger signal is produced.

5. The system of claim 2, wherein the pulse-energy measurement circuit further comprises a buffer amplifier located between the peak-hold circuit and the ADC, wherein the buffer amplifier is configured to receive the voltage signal corresponding to the peak of the voltage pulse and produce an output signal corresponding to the received voltage signal, wherein the output signal is supplied to the ADC.

6. The system of claim 2, wherein the pulse-energy measurement circuit further comprises a timer configured to determine a time of receipt for the test pulse of light.

7. The system of claim 1, wherein the pulse-energy measurement circuit comprises:
a detector configured to produce a pulse of photocurrent corresponding to the test pulse of light;
an electronic amplifier configured to produce a voltage pulse corresponding to the pulse of photocurrent; and
a plurality of comparators and a plurality of time-to-digital converters (TDCs), wherein:
each comparator of the plurality of comparators is coupled to a corresponding one of the TDCs and is configured to provide an electrical-edge signal to the corresponding TDC when the voltage pulse rises above or falls below a particular threshold voltage; and
the corresponding TDC is configured to produce a time value corresponding to a time when the electrical-edge signal was received.

8. The system of claim 7, wherein the numerical value corresponding to the individual energy amount of the test pulse of light is determined based on one or more time values produced by one or more of the TDCs.

9. The system of claim 7, further comprising a processor configured to determine a duration or a shape of the test pulse of light based on one or more time values produced by one or more of the TDCs.

10. The system of claim 9, wherein the processor is further configured to:
determine that the duration or the shape of the test pulse of light is different from an expected duration or shape; and
send, in response to determining that the duration or the shape of the test pulse of light is different from the expected duration or shape, an alert that the system is not operating properly.

11. The system of claim 1, further comprising a processor configured to determine the individual energy amount of the test pulse of light based on the numerical value corresponding to the individual energy amount of the test pulse of light.

12. The system of claim 1, further comprising a processor configured to determine an individual energy amount of the output pulse of light based on the individual energy amount of the test pulse of light.

13. The system of claim 12, wherein the individual energy amount of the output pulse of light (Eo) is determined from an expression E_{O} = E_{T}/ƒ, wherein E_{T} is the individual energy amount of the test pulse of light, and ƒ is a split ratio of the optical splitter.

14. The system of claim 12, further comprising:
a receiver is configured to detect a received pulse of light and determine an energy of the received pulse of light, the received pulse of light comprising a portion of the output pulse of light scattered by a target located a distance from the system; and
wherein the processor is further configured to determine a reflectivity of the target based on (i) the energy of the received pulse of light, (ii) the individual energy amount of the output pulse of light, and (iii) the distance from the system to the target.

15. The system of claim 1, further comprising a processor configured to:
determine that the individual energy amount of the test pulse of light among a plurality of test pulses of light is below a particular operating energy; and
send, in response to determining that the individual energy amount is below the particular operating energy, an instruction to adjust the light source.

16. The system of claim 15, wherein:
the light source comprises a fiber-optic amplifier comprising a pump laser diode; and
adjusting the light source includes increasing an electrical current supplied to the pump laser diode to increase an optical gain of the fiber-optic amplifier.

17. The system of claim 1, further comprising:
a processor configured to:
determine that the individual energy amount of the test pulse of light among a plurality of test pulses of light is below a particular minimum energy; and
send, in response to determining that the individual energy amount is below the particular minimum energy, an alert that the system is not operating properly.

18. The system of claim 17, wherein the alert comprises an instruction to shut down at least a portion of the system.

19. The system of claim 1, further comprising:
a processor configured to:
determine that the individual energy amount of the test pulse of light among a plurality of test pulses of light is outside an operating energy range; and
send, in response to determining that the individual energy amount is outside the operating energy range, an alert that the system is not operating properly.

20. The system of claim 1, further comprising:
a processor configured to:
based on the numerical value corresponding to the individual energy amount of the test pulse of light, send an instruction to adjust the light source; and
use a subsequent measurement received from the pulse-energy measurement circuit to verify a performance of the instruction to adjust the light source.

21. The system of claim 20, wherein the instruction to adjust the light source comprises an instruction to decrease an energy of one or more subsequently emitted pulses of light below a particular threshold energy, wherein the one or more subsequently emitted pulses of light correspond to output pulses of light that are directed by a scanner away from a window of the system.

22. The system of claim 1, further comprising:
a processor configured to:
determine that a time of receipt for the test pulse of light is outside a time-of-receipt interval; and
send, in response to determining that the time of receipt is outside the time-of-receipt interval, an alert that the system is not operating properly.

23. The system of claim 1, wherein the optical splitter is configured to split the emitted beam of light so that:
the individual energy amount of the test pulse of light is less than or equal to 2% of an energy of the emitted pulse of light; and
an energy of the output pulse of light is greater than or equal to 98% of the energy of the emitted pulse of light.

24. The system of claim 1, wherein the emitted pulse of light is one of a plurality of emitted pulses of light produced by the light source, wherein the emitted pulses of light have optical characteristics comprising:
a wavelength between 900 nanometers and 1700 nanometers;
a pulse energy between 0.1 µJ and 100 µJ;
a pulse repetition frequency between 80 kHz and 10 MHz; and
a pulse duration between 1 ns and 100 ns.

25. The system of claim 1, wherein the light source comprises a direct-emitter laser diode configured to produce the emitted beam of light.

26. The system of claim 1, wherein the light source comprises:
a seed laser diode configured to produce seed light; and
a semiconductor optical amplifier (SOA) configured to amplify the seed light to produce the emitted beam of light.

27. The system of claim 1, wherein the light source comprises:
a seed laser diode configured to produce seed light; and
a fiber-optic amplifier configured to amplify the seed light to produce the emitted beam of light.

28. The system of claim 1, wherein the light source comprises:
a seed laser diode configured to produce seed light;
a semiconductor optical amplifier (SOA) configured to amplify the seed light to produce amplified seed light; and
a fiber-optic amplifier configured to further amplify the amplified seed light to produce the emitted beam of light.

29. The system of claim 1, further comprising:
a scanner configured to scan the output beam of light across a field of regard of the system;
a receiver configured to detect a received pulse of light, the received pulse of light comprising a portion of the output pulse of light scattered by a target located a distance from the system; and
a processor configured to determine the distance from the system to the target based on a round-trip time for the portion of the output pulse of light to travel to the target and back to the system.

30. The system of claim 29, wherein the scanner comprises:
a first scan mirror comprising a polygon mirror, the polygon mirror configured to scan the output beam of light along a first scan axis to produce a plurality of scan lines; and
a second scan mirror configured to distribute the scan lines along a second scan axis different from the first scan axis.

31. A method comprising:
generating an emitted beam of light comprising an emitted pulse of light;
splitting the emitted beam of light to produce at least (i) a test beam of light comprising a test pulse of light, the test pulse of light comprising a first portion of the emitted pulse of light and (ii) an output beam of light comprising an output pulse of light, the output pulse of light comprising a second portion of the emitted pulse of light;
producing a pulse of photocurrent corresponding to the test pulse of light;
producing a voltage pulse corresponding to the pulse of photocurrent;
producing a voltage signal corresponding to a peak of the voltage pulse; and
determining a numerical value corresponding to an individual energy amount of the test pulse of light, wherein the numerical value is determined based on the voltage signal corresponding to the peak of the voltage pulse.

32. A system, comprising:
a light source configured to generate an emitted beam of light comprising an emitted pulse of light;
an optical splitter configured to split the emitted beam of light to produce at least (i) a test beam of light comprising a test pulse of light, the test pulse of light comprising a first portion of the emitted pulse of light and (ii) an output beam of light comprising an output pulse of light, the output pulse of light comprising a second portion of the emitted pulse of light allowed to at least in part exit the system;
a pulse-energy measurement circuit configured to receive the test pulse of light and produce a digital numerical value corresponding to a voltage peak of the test pulse of light; and
a processor configured to determine an individual energy amount of the test pulse of light based on the digital numerical value corresponding to the voltage peak of the test pulse of light.
